(19) United States
(12) Patent Application Publication
(10) Pub. No.: US 2026/0279280 A1
(43) Pub. Date: Sep. 17, 2026

(54) DISPLAY DEVICE

(71) Applicant: LG Display Co., Ltd., Seoul (KR)

(72) Inventors: Sangil SHIN, Paju-si (KR); Jisu CHOI, Paju-si (KR); Wanhee CHOI, Paju-si (KR)

(73) Assignee: LG Display Co., Ltd., Seoul (KR)

(21) Appl. No.: 19/392,797

(22) Filed: Nov. 18, 2025

(30) Foreign Application Priority Data
Mar. 12, 2025 (KR) 10-2025-0032241

(51) Int. Cl. G09G 3/3233

(52) U.S. Cl. CPC G09G 3/3233; G09G 2300/043; G09G 2300/0819; G09G 2300/0842; G09G 2320/0233

(57) ABSTRACT

Disclosed are a display device and a pixel control circuit. The display device includes: a display panel having an arrangement of pixels, and each of the pixels may include: a light emitting element comprising a plurality of light emitting units connected in series through a common node; a driving transistor having a first electrode connected to a high potential driving voltage through a first node, a gate electrode connected to a second node, and the second electrode connected to an anode electrode of the light emitting element through a third node; a compensation transistor connected between the second node and the third node and configured to receive a first scan signal through a gate electrode; a switching transistor connected between a data line and the first node and configured to receive a second scan signal through a gate electrode; and a common node reset transistor connected between the common node and a common node reset voltage and configured to receive a third scan signal through a gate electrode.

### CROSS REFERENCE TO RELATED APPLICATION

The present application claims priority and benefit to Korea Patent Application No. 10-2025-0032241, filed Mar. 12, 2025, the entire contents of which are hereby expressly incorporated for all purposes.

### TECHNICAL FIELD

The present disclosure relates to a display device.

### DESCRIPTION OF THE RELATED ART

With the progress of the information-oriented society, various types of demands for display devices which display an image are increasing. Further, various types of display devices such as a liquid crystal display device, and an organic light emitting display device have been used.

The organic light emitting display device improves its lifespan and efficiency by applying a light emitting element in a tandem structure. Such an emitting element in a tandem structure includes a first light emitting layer, a charge generation layer CGL and a second light emitting layer disposed between an anode electrode and a cathode electrode.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### BRIEF SUMMARY

The inventor has realized that: in the emitting element in a tandem structure, a voltage of the charge generation layer may be changed by a charge remaining on the charge generation layer after emitting light, a leakage asymmetry of the first light emitting layer and the second light emitting layer, a lateral leakage current introduced from an adjacent pixel and the like. This leads to an unwanted light emission in the light emitting element. Accordingly, an object of the present disclosure is to provide a display device that may remove influence of the lateral leakage current introduced from an adjacent pixel by resetting the charge generation layer of the tandem light emitting element.

Example embodiments provide a display device which includes a light emitting element in the tandem structure having a plurality of light emitting units, and resets a voltage of the charge generation layer during an anode reset period within one frame.

Example embodiments provide a display device which applies an anode reset voltage to the anode electrode during the anode reset period and applies a common node reset voltage which is different from the anode reset voltage to the charge generation layer.

Example embodiments provide a display device which includes a transistor connected between the charge generation layer and the common node reset voltage, and configured to receive a scan signal through a gate electrode.

Example embodiments provide a display device which varies the common node reset voltage during the operation.

Example embodiments provide a display device which forms a common node reset electrode on the same layer as the anode electrode of the light emitting element wherein the common node reset electrode and the charge generation layer to be in contact with each other.

One example embodiment is a display device including: a display panel having an arrangement of pixels, and each of the pixels may include: a light emitting element comprising a plurality of light emitting units connected in series through a common node; a driving transistor having a first electrode connected to a high potential driving voltage through a first node, a gate electrode connected to a second node, and the second electrode connected to an anode electrode of the light emitting element through a third node; a compensation transistor connected between the second node and the third node and configured to receive a first scan signal through a gate electrode; a switching transistor connected between a data line and the first node and configured to receive a second scan signal through a gate electrode; and a common node reset transistor connected between the common node and a common node reset voltage and configured to receive a third scan signal through a gate electrode.

The display device may further include: an anode reset transistor connected between the light emitting element and an anode reset voltage and configured to receive the third scan signal through a gate electrode, and the anode reset voltage and the common node reset voltage may have each different voltage value.

When the third scan signal is applied in a turn-on level during an anode reset period within one frame, the anode reset transistor may be turned on and apply an anode reset voltage to the anode electrode, and the common node reset transistor may be turned on and apply the common node reset voltage to the common node.

The display device may further include: an initialization transistor connected between an initialization voltage line and the second node and configured to receive a fourth scan signal through a gate electrode; a first light emitting transistor connected between the high potential driving voltage and the first node and configured to receive a light emitting signal through a gate electrode; a second light emitting transistor connected between the third node and the light emitting element and configured to receive the light emitting signal through a gate electrode; an on-bias transistor connected between the first node and an on-bias voltage and configured to receive the third scan signal through a gate electrode; and a storage capacitor connected between the high potential driving voltage and the second node.

At least part of the driving transistor, the compensation transistor, the switching transistor, and the common node reset transistor may be an LTPS transistor and a remaining other may be an oxide transistor.

The display device may further include: a substrate; a circuit element layer disposed on the substrate and comprising at least one thin film transistor; and a light emitting element layer disposed on the circuit element layer.

The light emitting element layer may include: the light emitting element; and a non-light emitting element electrically connected to the common node reset transistor.

The light emitting element may include: a first electrode; a second electrode disposed opposed to the first electrode; a first light emitting unit and a second light emitting unit disposed between the first electrode and the second electrode; and a charge generation layer interposed between the first light emitting unit and the second light emitting unit and configuring the common node.

The non-light emitting element may include: a common node reset electrode formed on a same layer as the first electrode and electrically connected to the common node reset transistor; the charge generation layer formed on the common node reset electrode; and a second electrode formed on the charge generation layer.

The charge generation layer and the second electrode may extend from the light emitting element to the non-light emitting element.

The first light emitting unit may include: a hole transporting layer; and a first light emitting layer disposed on the hole transporting layer; and the second light emitting unit may include: a second light emitting layer; and a second electron transporting layer on the second light emitting layer, and the second electron transporting layer may extend from the light emitting element to the non-light emitting element.

In the light emitting element and the non-light emitting element, the charge generation layer may include: a negative charge generation layer disposed adjacent to the first light emitting unit; and a positive charge generation layer disposed adjacent to the second light emitting unit.

In the light emitting element, the charge generation layer may include: a negative charge generation layer disposed adjacent to the first light emitting unit; and a positive charge generation layer disposed adjacent to the second light emitting unit, and in the non-light emitting element, the charge generation layer may include: the positive charge generation layer.

The common node reset electrode may be formed per one, or two or more pixels.

The circuit element layer may include: a first buffer layer disposed on the substrate; a first semiconductor layer of a first thin film transistor disposed on the buffer layer; a first insulation layer disposed on the first semiconductor layer; a first gate electrode of the first thin film transistor disposed on the first insulation layer; a second insulation layer of the first thin film transistor disposed on the gate electrode; a second buffer layer disposed on the second insulation layer; a second semiconductor layer of a second thin film transistor disposed on the second buffer layer; a third insulation layer disposed on the second semiconductor layer; a second gate electrode of the second thin film transistor disposed on the third insulation layer; a fourth insulation layer of the second thin film transistor disposed on the gate electrode; source and drain electrodes of the first and second thin film transistors disposed on the fourth insulation layer; and a planarization layer disposed on the source and drain electrodes.

The first thin film transistor may be part of the driving transistor, the compensation transistor, the switching transistor, and the common node reset transistor, and the second thin film transistor may be a remaining other of the driving transistor, the compensation transistor, the switching transistor, and the common node reset transistor.

The display device may further include: a color filter layer disposed on the light emitting element layer and comprising color filters and a black matrix disposed between the color filters, and the black matrix may be formed such that at least one region thereof overlaps the non-light emitting element.

Another example embodiment is a display device including: a substrate; a circuit element layer disposed on the substrate and including at least one thin film transistor; and a light emitting element layer disposed on the circuit element layer and including a light emitting element and a non-light emitting element.

The light emitting element may include: a first electrode; a second electrode disposed opposed to the first electrode; a first light emitting unit and a second light emitting unit disposed between the first electrode and the second electrode; and a charge generation layer interposed between the first light emitting unit and the second light emitting unit.

The non-light emitting element may include: a common node reset electrode formed on a same layer as the first electrode; the charge generation layer formed on the common node reset electrode; and a second electrode formed on the charge generation layer.

The charge generation layer and the second electrode may extend from the light emitting element to the non-light emitting element.

In the light emitting element and the non-light emitting element, the charge generation layer may include: a negative charge generation layer disposed adjacent to the first light emitting unit; and a positive charge generation layer disposed adjacent to the second light emitting unit.

In the light emitting element, the charge generation layer may include: a negative charge generation layer disposed adjacent to the first light emitting unit; and a positive charge generation layer disposed adjacent to the second light emitting unit, and in the non-light emitting element, the charge generation layer may include: the positive charge generation layer.

The circuit element layer may include: a driving transistor connected to the light emitting element; and a common node reset voltage transistor having a first electrode connected to the charge generation layer through the common node reset electrode of the non-light emitting element, and a second electrode connected to a common node reset voltage.

Another example embodiment is a pixel control circuit, comprising: a light emitting element comprising a plurality of light emitting units connected in series through a common node; a driving transistor having a first electrode connected to a high potential driving voltage through a first node, a gate electrode connected to a second node, and the second electrode connected to an anode electrode of the light emitting element through a third node; a compensation transistor connected between the second node and the third node and configured to receive a first scan signal through a gate electrode; a switching transistor connected between a data line and the first node and configured to receive a second scan signal through a gate electrode; and a common node reset transistor connected between the common node and a common node reset voltage and configured to receive a third scan signal through a gate electrode.

The display device according to example embodiments may remove influence of a parasitic capacitor or a parasitic resistance of a tandem light emitting element by resetting the charge generation layer of the tandem light emitting element.

The display device according to example embodiments may remove influence of the lateral leakage current introduced from an adjacent pixel by resetting the charge generation layer of the tandem light emitting element.

The display device according to example embodiments may reduce a luminance difference between a first light emitting element and a second light emitting element at an initial time in which a gray pattern is displayed from a black pattern by preventing variation of a voltage of the charge generation layer of the tandem light emitting element.

The display device according to example embodiments may reduce a potential difference between a first light emitting element and a second light emitting element by preventing variation of a voltage of the charge generation layer of the tandem light emitting element, thereby the unwanted light emission in the first light emitting element and the second light emitting element can be prevented.

The display device according to example embodiments may solve a problem in that a voltage variation is generated as the charge generation layer is floated during the anode reset period within one frame and variation occurs in optical characteristics.

The display device according to example embodiments may prevent variation of a voltage of the charge generation layer by resetting a voltage of the charge generation layer during the anode reset period.

Objects of the present disclosure are not limited to the above-described object, and other objects of the present disclosure not yet described will be more clearly understood by those skilled in the art from the following detailed description.

### BRIEF DESCRIPTION OF THE SEVERAL VIEWS OF THE DRAWINGS

The above and other objects, features, and advantages of the present disclosure will become more apparent to those of ordinary skill in the art by describing example embodiments thereof in detail with reference to the attached drawings, in which:

FIG. 1 is a block diagram of a configuration of a display device according to an example embodiment.

FIG. 2 is a circuit diagram of a pixel according to an example embodiment.

FIG. 3 shows an equivalent circuit of a tandem light emitting element illustrated in FIG. 2.

FIG. 4 is a view illustrating a method for driving a pixel illustrated in FIG. 2 according to an example embodiment.

FIG. 5 is a cross-sectional view illustrating a stacked shape of a display device according to an example embodiment.

FIG. 6 is a view illustrating a structure of a light emitting element according to an example embodiment.

FIG. 7 is a view illustrating a structure of a non-light emitting element according to an example embodiment.

FIG. 8 is a view illustrating a method for forming a non-light emitting element according to an example embodiment.

FIG. 9 is a view illustrating a structure of a non-light emitting element according to another example embodiment.

FIG. 10 is a view illustrating a method for forming a non-light emitting element according to another example embodiment.

FIG. 11 is a cross-sectional view illustrating a stacked shape of a display device according to another example embodiment.

FIG. 12 is a plan view illustrating a region of a display panel according to an example embodiment.

FIG. 13 is a view illustrating a region of a display panel according to another example embodiment.

FIG. 14 is a view illustrating a region of a display panel according to still another example embodiment.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers of elements and the like illustrated in the accompanying drawings for describing the example embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Hereinafter, embodiments of the disclosure will be described with reference to the drawings. In this specification, when a component (or, an area, a layer, a part, etc.) is referred to as being “on,” “connected to” or “combined to” another component, the component may be directly on, connected to, or combined to the other component, or a third component therebetween may be present.

Like reference numerals refer to like elements throughout. Additionally, in the drawings, the thicknesses, proportions, and dimensions of components may be exaggerated for ease of description and clarity. “And/or” includes all of one or more combinations defined by related components.

It will be understood that when the terms “first” and “second” are used herein to describe various components, these components should not be limited by these terms. The above terms are used only to distinguish one component from another. For example, a first component may be referred to as a second component and vice versa without departing from the scope of the present disclosure. Singular expressions and terms used herein also encompass or include plural expressions and terms, unless the context clearly indicates otherwise.

When the position relation between two parts is described using the terms such as “on,” “above,” “over,” “below,” “under,” “beside,” “beneath,” “near,” “close to” “adjacent to,” “on a side of,” “next,” one or more parts may be positioned between the two parts unless the terms are used with the term “immediately” or “directly.”

Spatially relative terms, such as “beneath,” “below,” “lower,” “above,” “upper” and the like, may be used herein for ease of description to describe one element or feature's relationship to another element(s) or feature(s) as illustrated in the drawings. The above terms are relative concepts and are explained based on the directions indicated in the drawing.

When a temporal relationship is described, for example, when terms for temporal relationship of events such as “after,” “subsequently,” “next,” and “before” are used, there may also be the case in which the events are not continuous, unless “immediately” or “directly” is used.

The word “example” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In various embodiments of the disclosure, the term “include,” “have,” “comprise,” “contain,” “constitute,” “make up of,” “formed of,” and “consist of” specifies a property, a fixed number, a step, a process, an element and/or a component, or a combination thereof, but does not exclude presence or addition of other properties, fixed numbers, steps, processes, elements and/or components, or a combination thereof.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In the specification, in adding reference numerals for elements in each drawing, it should be noted that like reference numerals already used to denote like elements in other drawings are used for elements wherever possible. In addition, the dimension scales of constituent elements shown in the drawings may be different from actual dimension scales, for convenience of description. That is, the dimension scales of constituent elements shown in the drawings should not be interpreted to be the same as those shown in the drawings.

Hereinafter, a display device according to example embodiments of the present disclosure will be described in detail with reference to accompanying drawings.

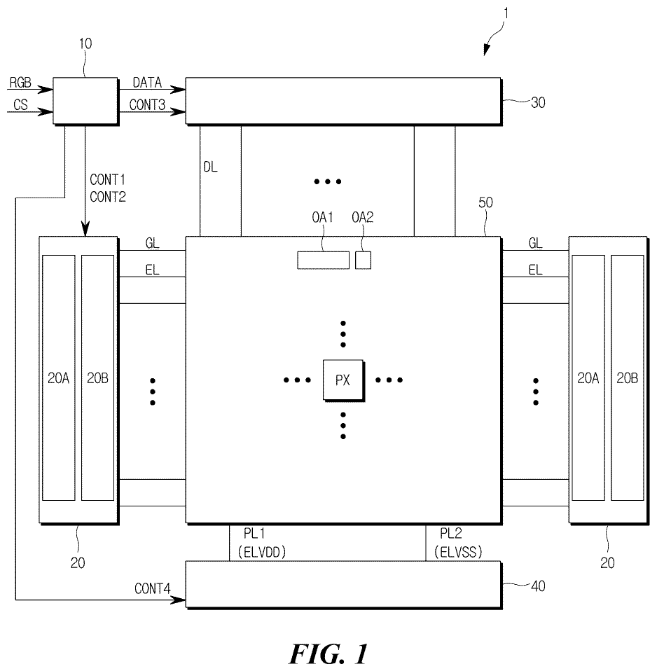

FIG. 1 is a block diagram of a configuration of a display device according to an example embodiment.

Referring to FIG. 1, the display device 1 may include a timing controller 10, a gate driver 20, a data driver 30, a power supply unit 40, and a display panel 50.

The timing controller 10 may be configured by being integrated to various processors, for example, a micro-processor, a mobile processor, an application processor, and the like according to devices mounted therein. The timing controller 10 may receive a video signal RGB and a control signal CS from an external host system and the like. The video signal RGB may include a plurality of grayscale data. The control signal CS may include, for example, a horizontal synchronization signal, a vertical synchronization signal, a data enable signal and a main clock signal. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel.

The timing controller 10 processes the video signal RGB and the control signal CS to be suitable to operational conditions of the display panel 50, and may generate and output image data DATA, a gate driving control signal CONT1, a light emission driving control signal CONT2, a data driving control signal CONT3, and a power supply control signal CONT4.

In an example embodiment, the timing controller 10 may control an operation timing of the gate driver 20 and the data driver 30 with a frame frequency (Hz) obtained by multiplying i (i is an integer greater than 0) to an input frame frequency. The input frame frequency is 60 Hz in an NTSC (National Television Standards Committee) method, and 50 Hz in PAL (Phase-Alternating Line) method, but is not limited thereto.

The timing controller 10 generates a signal so that the pixel PX can be driven at various refresh rates. The refresh rate may be defined as a quantity of frames transmitted per second. That is, the timing controller 10 may be driven in a Variable Refresh Rate (VRR) mode. In the VRR mode, the timing controller 10 may generate related signals to be provided to the pixel PX so that the pixel PX can be driven at a varied refresh rate. For example, the timing controller 10 may adjust a time point of applying the control signals CS, mask the control signals CS, or vary a frequency of the control signals CS.

The timing controller 10 may be configured to be coupled with various processors, for example, a microprocessor, a mobile processor, an application processor, etc., in accordance with a device mounted therein.

The timing controller 10 may be implemented in a separate component from the data driver 30, or integrated with the data driver 30, so that the timing controller 10 and the data driver 30 can be implemented in a single integrated circuit.

The timing controller 10 may be a timing controller used in the typical display technology or a control apparatus/device capable of additionally performing other control functionalities in addition to the typical function of the timing controller. In one or more embodiments, the timing controller 10 may be one or more other control circuits different from the timing controller, or a circuit or component in the control apparatus/device. The timing controller 10 may be implemented using various circuits or electronic components such as an integrated circuit (IC), a field programmable gate array (FPGA), an application specific integrated circuit (ASIC), a processor, and/or the like.

The timing controller 10 may be mounted on a printed circuit board, a flexible printed circuit, or the like, and may be electrically connected to the data driver 30 and the gate driver 20 through the printed circuit board, the flexible printed circuit, and/or the like.

The timing controller 10 can transmit signals to, and receive signals from, the data driver 30 via one or more predetermined interfaces. For example, such interfaces may include a low voltage differential signaling (LVDS) interface, an embedded clock point-point interface (EPI), a serial peripheral interface (SPI), and the like. However, the present disclosure are not limited thereto.

The gate driver 20 may include a scan driving circuit 20A configured to generate scan signals based on a gate driving control signal CONT1 input from the timing controller 10. The scan driving circuit 20A may provide the generated scan signals to the pixels PX through a plurality of scan lines GL. In an example embodiment, one pixel PX may be configured to receive a plurality of scan signals having each different waveform. In such an example embodiment, the scan driving circuit 20A may provide a plurality of scan signals to the pixels PX through corresponding scan lines GL, respectively.

The gate driver 20 may further include an emission driving circuit 20B configured to generate emission control signals based on the light emission driving control signal CONT2 input from the timing controller 10. The emission driving circuit 20B may provide the generated emission control signals to the pixels PX through emission lines EL.

The gate driver 20 may be formed in a gate-in-panel manner in which the gate driver 20 is mounted in the display panel 50. The gate driver 20 may be disposed on one side of the display panel 50, or on both sides (for example, a left side and a right side) of the display panel 50 as illustrated. According to a driving method, a panel design method, and the like, the gate driver 20 may be disposed on both sides (for example, a left side and a right side) of the display panel 50 as illustrated, or may be connected to two or more side surfaces among four side surfaces of the display panel 50.

The data driver 30 may generate data signals based on the data driving control signal CONT3 and image data DATA output from the timing controller 10. The data driver 30 may provide the generated data signals to the pixels PX through a plurality of data lines DL.

The power supply unit 40 may generate a high potential driving voltage ELVDD and a low potential driving voltage ELVSS to be provided to the display panel 50 based on the power supply control signal CONT4. The power supply unit 40 may provide the generated driving voltages ELVDD and ELVSS to the pixels PX through corresponding power lines PL1 and PL2. In addition, the power supply unit 40 may further generate an initialization voltage for driving the pixel PX, an on-bias voltage and/or an anode reset voltage, and provide them to the pixels PX through a corresponding voltage line.

The display panel 50 may be implemented as a transmissive or a non-transmissive display panel. The transmissive display panel may be applied to a transparent display device of which an image is displayed in the screen and a real background object is visible. The display panel 50 may be manufactured as a flexible display panel. The flexible display panel may be implemented as an OLED panel which uses a plastic substrate.

On the display panel 50, a plurality of pixels PX (or referred to as sub-pixels) is disposed. The pixels PX may be disposed, for example, in a matrix form on the display panel 50. The pixels PX disposed in one pixel row are connected to the same scan line GL and light emission line EL, and the pixels disposed in one pixel column are connected to the same data line DL. The pixels PX may emit light at luminance corresponding to a data signal and a scan signal supplied through the scan line GL and the data line DL in response to a light emission control signal applied through the light emission line EL.

In an example embodiment, each pixel PX may display one color among red, green and blue. In another example embodiment, each pixel PX may display one color among cyan, magenta and yellow. In various example embodiments, each pixel PX may display one color among red, green, blue and white. The plurality of pixels may be variously modified in colors and configurations, as necessary. However, the present disclosure is not limited thereto.

For example, the plurality of pixels may include red, green, and blue pixels, in which the red, green, and blue pixels may be disposed in a repeated manner. Alternatively, the plurality of pixels may include red, green, blue, and white pixels, in which the red, green, blue, and white pixels may be disposed in a repeated manner, or the red, green, blue, and white pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the pixels are not limiting, and may be configured in various forms according to light-emitting characteristics, device lifespans, and device specifications.

Meanwhile, the pixels may have different light-emitting areas according to light-emitting characteristics. For example, a pixel that emits light of a color different from that of a blue pixel may have a different light-emitting area from that of the blue pixel. For example, the red pixel, the blue pixel, and the green pixel, or the red pixel, the blue pixel, the white pixel, and the green pixel may each has a different light-emitting area.

In an example embodiment, in the display panel 50, one or more optical regions OA1 and OA2 may be disposed. The one or more optical regions OA1 and OA2 may overlap one or more opto-electronics such as a photographing device such as a camera (an image sensor) and the like, and a detection sensor such as a proximity sensor, an illuminance sensor, and the like.

One or more optical regions SA1 and SA2 may have a light transmitting structure, and have a transmittance above a certain level for an operation of the opto-electronics. The light transmitting structure may be configured by patterning a cathode electrode in a portion in which the pixel PX is not disposed. The cathode electrode may be removed by using a laser, or may be patterned by selectively forming the cathode electrode through a cathode deposition prevention layer.

In addition, the light transmitting structure may be formed by separating the light emitting element in the pixel PX. In such an example embodiment, the light emitting element of the pixel PX may be positioned in the optical region OA1 and OA2, a plurality of transistors configuring the pixel PX may be disposed around the optical region OA1 and OA2, and the light emitting element and the pixel may be electrically connected to each other through a transparent metal layer.

A quantity of the pixel PX per unit area in the one or more optical regions OA1 and OA2 may be fewer than a quantity of the pixel PX per unit area in the remaining other region except the optical regions OA1 and OA2. That is, a resolution of the one or more optical regions OA1 and OA2 may be lower than a resolution of the remaining other region.

In an example embodiment, a touch sensor may be further disposed on the display panel 50. A touch input may be sensed by using touch sensors or pixels PX. The touch sensors may be disposed on the display panel 50 as an on-cell type or an add-on type, or may be implemented as an in-cell type which is embedded into the display panel 50.

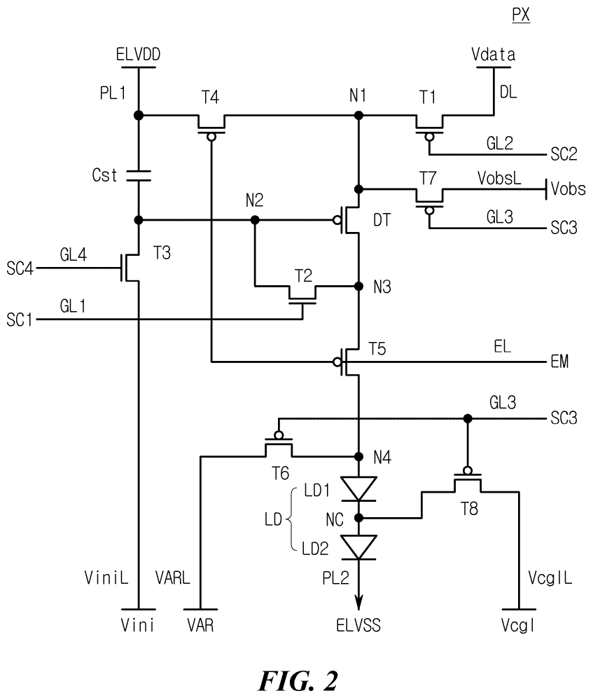

FIG. 2 is a circuit diagram of the pixel according to an example embodiment.

Referring to FIG. 2, the pixel PX according to an example embodiment may include a driving transistor DT, a light emitting element LD connected to the driving transistor DT, and a control circuit configured to control an amount of a driving current to be applied to the light emitting element LD through the driving transistor DT. For example, the control circuit may include first to eighth transistors T1 to T8, and a storage capacitor Cst.

A first electrode of the driving transistor DT is connected to the data line DL through a first node N1, and a second electrode thereof is connected to the light emitting element LD through a third node N3. A gate electrode of the driving transistor DT is configured to receive a high potential driving voltage ELVDD through a second node N2 (connected to a high potential driving voltage line PL1). The driving transistor DT may be turned on according to a voltage difference between the second node N2 and the first node N1 (that is, a gate-source voltage), and may control an amount of the driving current flowing to the light emitting element LD.

A first electrode of the first transistor T1 is connected to the data line DL, and a second electrode thereof is connected to the first electrode of the driving transistor DT through the first node N1. A gate electrode of the first transistor T1 may be connected to a second scan line GL2 and may receive a second scan signal SC2. The first transistor T1 may be turned on according to the second scan signal SC2 applied to the second scan line GL2, and may transmit a data voltage Vdata applied to the data line DL to the first node N1. Such a first transistor T1 may be referred to as a switching transistor.

The second transistor T2 is connected between the second node N2 and the third node N3. A gate electrode of the second transistor T2 may be connected to a first scan line GL1 and may receive a first scan signal SC1. The second transistor T2 may be turned on according to the first scan signal SC1 applied to the first scan line GL1, and may electrically connect the gate electrode of the driving transistor DT and the second electrode of the driving transistor (DT). Such a second transistor T2 may be referred to as a compensation transistor.

A first electrode of the third transistor T3 is connected to the second node N2, and a second electrode thereof is configured to receive an initialization voltage Vini (connected to an initialization voltage line ViniL). A gate electrode of the third transistor T3 may be connected to a fourth scan line GL4 and may receive a fourth scan signal SC4. The third transistor T3 may be turned on according to the fourth scan signal SC4 applied to the fourth scan line GL4, and may apply an initialization voltage Vini to the gate electrode of the driving transistor DT. Such a third transistor T3 may be referred to as an initialization transistor. The initialization voltage may be, for example, −5V, but is not limited thereto.

A first electrode of the fourth transistor T4 is configured to receive the high potential driving voltage ELVDD (connected to the high potential driving voltage line PL1), and a second electrode thereof is connected to the driving transistor DT through the first node N1. A gate electrode of the fourth transistor T4 may be connected to a light emission line EL and may receive a light emitting signal EM. The fourth transistor T4 may connect the high potential driving voltage line PL1 and the driving transistor DT to each other in response to the light emitting signal EM applied to the light emission line EL.

A first electrode of a fifth transistor T5 may be connected to the driving transistor DT through the third node N3, and a second electrode thereof may be connected to the light emitting element LD through a fourth node N4. A gate electrode of the fifth transistor T5 may be connected to the light emission line EL, and may receive the light emitting signal EM. The fifth transistor T5 may connect the driving transistor DT and the light emitting element LD to each other in response to the light emitting signal EM applied to the light emission line EL.

When the fourth transistor T4 and the fifth transistor T5 are turned on, a current path is formed between the high potential driving voltage ELVDD and the low potential driving voltage ELVSS, and a driving current may flow to the light emitting element LD, thereby the light emitting element LD may emit light. Such fourth transistor T4 and the fifth transistor T5 may be referred to as light emitting transistors.

A first electrode of a sixth transistor T6 is configured to receive an anode reset voltage VAR (connected to an anode reset voltage line VARL), and a second electrode thereof is connected to the fourth node N4. A gate electrode of the sixth transistor T6 may be connected to a third scan line GL3 and may receive a third scan signal SC3. The sixth transistor T6 may be turned on according to the third scan signal SC3 applied to the third scan line GL3, and may apply the anode reset voltage VAR to the anode electrode of the light emitting element LD. Such a sixth transistor T6 may be referred to as an anode reset transistor.

In an example embodiment, the anode reset voltage VAR may be provided to each pixel PX with the same or different value. For example, with respect to a pixel PX (hereinafter, a red pixel) configured to display a red color, the anode reset voltage VAR may be about −8.1V. With respect to a pixel PX (hereinafter, a green pixel, a blue pixel) configured to display a green color, or a blue color, the anode reset voltage VAR may be about −7V. However, the example embodiment is not limited thereto.

A first electrode of a seventh transistor T7 is connected to the first node N1, and a second electrode thereof is configured to receive an on-bias voltage Vobs (connected to an on-bias voltage line VobsL). A gate electrode of the seventh transistor T7 is connected to the third scan line GL3, and may receive the third scan signal SC3. The seventh transistor T7 may be turned on according to the third scan signal SC3 applied to the third scan line GL3, and may apply the on-bias voltage Vobs to the second electrode of the driving transistor DT. Such a seventh transistor T7 may be referred to as an on-bias transistor.

A first electrode of an eighth transistor T8 is configured to receive a common node reset voltage Vcgl (connected to a common node reset voltage line VcglL), and a second electrode thereof is connected to a common node NC. A gate electrode of the eighth transistor T8 is connected to the third scan line GL3, and may receive the third scan signal SC3. The eighth transistor T8 may be turned on according to the third scan signal SC3 applied to the third scan line GL3, and may apply the common node reset voltage Vogl to the common node NC. Such an eighth transistor T8 may be referred to as a common node reset transistor.

The common node reset voltage Vogl may be a voltage different from the anode reset voltage VAR, but is not limited thereto. For example, the common node reset voltage Vogl may have a value between the low potential driving voltage ELVSS and a voltage which will be applied to the anode electrode at the highest greyscale. In such an example embodiment, the common node reset voltage Vcgl may have a value between about −8.8V and 1.9V. The common node reset voltage Vogl may be selected in a given range, and may vary based on a temperature, a degree of deterioration, and a driving time of the display panel 50 (FIG. 1). For example, the display device 1 may prestore a voltage value of the common node reset voltage Vogl which is differently set in response to a temperature, a degree of deterioration, and a driving time of the display panel 50 through an additional memory and the like. Such a voltage value may be stored in a form of a look-up table (LUT), for example. The display device 1 may select a voltage value of the common node reset voltage Vogl, in response to a temperature, a degree of deterioration, and a driving time of the display panel 50 determined through pixel sensing and the like, from the look-up table, and may adjust the common node reset voltage Vogl with the selected voltage value.

The storage capacitor Cst is disposed between the high potential driving voltage line PL1 and the second node N2. The storage capacitor Cst may store a voltage corresponding to a voltage difference between the high potential driving voltage ELVDD and the second node N2, and maintain the stored voltage during one frame period, thereby stabilizing a voltage of the gate electrode (that is, the second node N2) of the driving transistor DT.

An anode electrode of the light emitting element LD may be connected to the fourth node N4, and a cathode electrode thereof may be connected to the low potential driving voltage ELVSS (connected to a low potential driving voltage line PL2). The low potential driving voltage ELVSS may be about −8.8V, but is not limited thereto.

When the driving transistor DT, the fourth transistor T4, and the fifth transistor T5 are turned on, a current path is formed between the high potential driving voltage ELVDD and the low potential driving voltage ELVSS, and a driving current may flow to the light emitting element LD. The light emitting element LD may emit light at luminance corresponding to an amount of the driving current applied thereto.

In an example embodiment, T1 may be function as a switching transistor, T2 may be function as a compensation transistor, T3 may be function as an initialization transistor, T4 and T5 may be function as light emitting transistors, T6 may be function as an anode reset transistor, T7 may be function as an on-bias transistor, and T8 may be function as a common node reset transistor, however, the present disclosure is not limited thereto.

In an example embodiment, the light emitting element LD may have a tandem structure in which a plurality of light emitting units LD1 and LD2 are connected in series. The light emitting element LD has a structure in which the plurality of light emitting units LD1 and LD2 are stacked, and therefore, may improve a luminescence purity and luminescence efficiency. The light emitting units LD1 and LD2 disposed adjacent to each other may be connected through the common node NC. The common node NC is an organic layer configuring the light emitting element LD, and may correspond to, for example, the charge generation layer.

In the illustrated example embodiment, the light emitting element LD is formed of two light emitting units LD1 and LD2. However, in other example embodiments, the light emitting element LD may include a greater quantity of light emitting units LD. At this instance, the light emitting units LD1 and LD2 in each of the adjacent light emitting element LD may be connected to each other through the common node NC. In such an example embodiment, a common node reset transistor T8 connected to each of the plurality of common nodes NC may be provided.

In the example embodiment illustrated in FIG. 2, the pixel PX may include a low temperature poly-silicon (LTPS) transistor. The LTPS transistor includes a gate electrode, a source electrode, and a drain electrode. The LTPS transistor includes an active layer formed of polysilicon. Such an LTPS transistor may be configured as a P-type transistor or an N-tyle transistor. The LTPS transistor has high electron mobility and thus, has a fast driving characteristic.

In an example embodiment, the driving transistor DT may be formed of the LTPS transistor. In addition, at least one transistor T1, T4, T5, T6, T7 and T8 which has a fast driving characteristic among the transistors T2 to T8 may be configured as the LTPS transistor. In particular, as the fourth transistor T4 and the fifth transistor T5 are configured as the LTPS transistor, when the light emitting signal EM is applied in a turn-on level, the fourth and fifth transistors T4 and T5 may be turned on fast and a response speed for light emission may become fast.

In addition, in an example embodiment, the pixel PX may be a hybrid type which further includes an oxide semiconductor transistor. The oxide semiconductor transistor includes a gate electrode, a source electrode, and a drain electrode. The oxide semiconductor transistor includes an active layer formed of an oxide semiconductor. Here, the oxide semiconductor may be set as an amorphous or crystalline oxide semiconductor. The oxide semiconductor transistor may be configured as an n-type transistor. The oxide semiconductor transistor may be formed through a low temperature process and has a lower charge mobility than that of the low temperature poly-silicon (LTPS) transistor. Such an oxide semiconductor transistor has an excellent off current characteristic.

In an example embodiment of FIG. 2, the second and third transistors T2 and T3 are configured as the LTPS transistor. However, the example embodiment is not limited thereto.

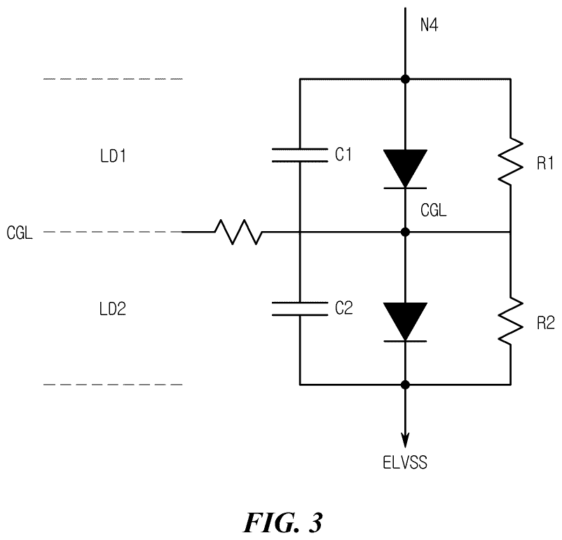

FIG. 3 shows an equivalent circuit of the tandem light emitting element illustrated in FIG. 2.

Referring to FIG. 3, the light emitting element LD includes the first and second light emitting units LD1 and LD2. The light emitting element LD may include a first parasitic capacitor C1 formed between the anode electrode and the charge generation layer CGL, that is, the common node NC (FIG. 1), and a second parasitic capacitor C2 formed between the charge generation layer CGL and the cathode electrode. In addition, the light emitting element LD may include a first parasitic resistance R1 formed between the anode electrode and the charge generation layer CGL, and a second parasitic resistance R2 formed between the charge generation layer CGL and the cathode electrode. The first and second parasitic capacitors C1 and C2 may have each different capacitance value. In addition, the first and second parasitic resistances R1 and R2 may have each different resistance value.

A potential difference between the first light emitting unit LD1 and the second light emitting unit LD2, that is, a voltage of the charge generation layer CGL may vary by the first and second parasitic capacitors C1 and C2 or the first and second parasitic resistances R1 and R2. Light emission of the first light emitting unit LD1 or the second light emitting unit LD2 at an unwanted time point may be attributable to the variation of the voltage of the charge generation layer.

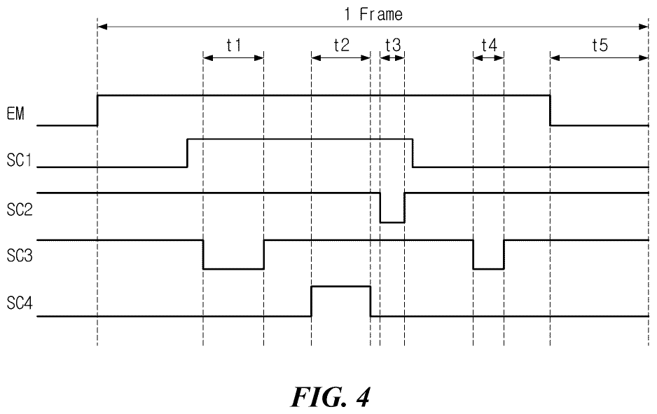

FIG. 4 is a view illustrating a method for driving the pixel illustrated in FIG. 2 according to an example embodiment.

Referring to FIGS. 2 and 4 together, one frame may include a first on-bias and anode reset period t1, an initialization period t2, a sampling and programming period t3, a second on-bias and anode reset period t4, and a light emission period t5.

In the first on-bias and anode reset period t1, a voltage of the second electrode of the driving transistor DT is biased, and a voltage of the anode electrode of the light emitting element LD is reset.

In more detail, in the first on-bias and anode reset period t1, the first scan signal SC1 in a turn-on level (for example, a high level) is applied, and accordingly, the second transistor T2 is turned on, thereby electrically connecting the second node N2 and the third node to each other.

In addition, in the first on-bias and anode reset period t1, the third scan signal SC3 in a turn-on level (for example, a low level) is applied, the sixth transistor T6 and the seventh transistor T7 are turned on, and the anode reset voltage VAR and the on-bias voltage Vobs may be applied to the anode electrode of the light emitting element LD and the first electrode of the driving transistor DT. A voltage of the first electrode of the driving transistor DT is set as the on-bias voltage Vobs, and therefore, an on-bias stress of the driving transistor DT may be reduced.

The eighth transistor T8 may be further turned on in response to the third scan signal SC3. As a result, the common node reset voltage Vogl may be further applied to the common node NC of the light emitting element LD.

In the initialization period t2, voltages of the major nodes of the pixel PX are initialized.

In more detail, in the initialization period t2, the third scan signal SC3 is changed over to a turn-off level (for example, a high level), and the sixth transistor T6 to the eighth transistor T8 may be turned off.

In addition, in the initialization period t2, the fourth scan signal SC4 in a turn-on level (for example, a high level) is applied, and accordingly, the third transistor T3 is turned on, thereby being able to apply the initialization voltage Vini to the gate electrode of the driving transistor DT. The initialization voltage Vini may be further applied to the gate electrode of the driving transistor DT through the second transistor DT2 in a turn-on state. The initialization voltage Vini may be a positive voltage in a low level, and may be a voltage corresponding to black luminance, but is not limited thereto.

A voltage difference between the high potential driving voltage ELVDD and the initialization voltage Vini which is a voltage of the second node N2 is stored in the storage capacitor Cst.

In the sampling and programming period t3, a threshold voltage Vth of the driving transistor DT is sampled, and data voltage Vdata is programmed into the pixel PX.

In more detail, in the sampling and programming period t3, the fourth scan signal SC4 is changed over to a turn-off level (for example, a low level), and thus, the third transistor T3 may be turned off.

In addition, in the sampling and programming period t3, the second scan signal SC2 in a turn-on level (for example, a low level) is applied and accordingly, the first transistor T1 is turned on, thereby the data voltage Vdata may be applied to the first electrode of the driving transistor DT. The gate electrode and the second electrode of the driving transistor DT may be electrically connected to each other by the second transistor T2 in a turn-on state. At this instance, the second electrode is floated and gets into a voltage variable state.

In the sampling and programming period t3, the gate-source voltage Vgs of the driving transistor DT is set as a voltage difference between the data voltage Vdata and the initialization voltage Vini, to be greater than the threshold voltage Vth, in other words, to be an on-condition. Therefore, the driving transistor DT is turned on, and may supply the source-drain current to the third node until the gate-source voltage Vgs reaches the threshold voltage Vth of the driving transistor DT. A voltage of the gate electrode and the second node N2 may increase gradually from the initialization voltage Vini, and may converge to a sum (Vdata+Vth) of the data voltage Vdata and the threshold voltage Vth.

A voltage difference (ELVDD−(Vdata+Vth)) between the high potential driving voltage ELVDD and the second node N2 is stored in the storage capacitor Cst. A voltage programmed into the gate electrode of the driving voltage DT in the sampling and programming period t3 is a voltage for which the threshold voltage Vth is compensated.

In the second on-bias and anode reset period t4, the first scan signal SC1 and the second scan signal SC2 are changed over to a turn-off level, and the first transistor T1 and the second transistor T2 may be turned off.

In addition, in the second on-bias and anode reset period t4, the third scan signal SC3 in a turn-on level (for example, a low level) is applied, and the sixth transistor T6 and the seventh transistor T7 are turned on, thereby the anode reset voltage VAR and the on-bias voltage Vobs may be applied to the anode electrode of the light emitting element LD and the first electrode of the driving transistor DT, respectively. The on-bias voltage Vobs applied in the second on-bias and anode reset period t4 may have the same or a different level from that of the on-bias voltage Vobs applied in the first on-bias and anode reset period t1.

The eighth transistor T8 may be further turned on in response to the third scan signal SC3. As a result, the common node reset voltage Vogl may be further applied to the common node NC of the light emitting element LD.

In the light emission period t5, the light emitting element LD which is turned on may emit light at luminance corresponding to a magnitude of the programmed voltage. In more detail, in the light emission period t5, the third scan signal SC3 may be changed over to a turn-off level and the light emitting signal EM in a turn-on level (for example, a low level) may be applied.

When the fourth and fifth transistors T4 and T5 are turned on in response to the light emitting signal EM, a driving current may flow from the high potential driving voltage ELVDD to the light emitting element LD via the driving transistor DT. A voltage of the fourth node N4 rises to the operating point voltage of the light emitting element LD by the driving current. At this instance, the gate-source voltage Vgs of the driving transistor DT is maintained as a programmed voltage by the storage capacitor Cst. The light emitting element LD emits light by the driving current when the voltage of the fourth node N4 becomes equal to the operating point voltage. Here, the voltage programmed into the gate electrode of the driving voltage DT is a voltage for which the data voltage Vdata is compensated by as much as the threshold voltage Vth. Therefore, deterioration of the driving transistor DT may be compensated.

In the example embodiment as above, when the anode reset voltage VAR is applied to the anode electrode of the light emitting element LD, the common node reset voltage Vogl is applied to the common node NC which connects the light emitting units LD1 and LD2 of the light emitting element LD to each other. In more detail, in the first and second on-bias and anode reset periods t1 and t4, the sixth transistor T6 applies the anode reset voltage VAR to the anode electrode in response to the third scan signal SC3 in a turn-on level, and at the same time, the eighth transistor T8 applies the common node reset voltage Vogl to the common node NC in response to the third scan signal SC3 in a turn-on level.

By resetting the common node NC in the manner described as above, it is possible to prevent variation of the voltage due to floating of the charge generation layer during the anode reset, and occurrence of unwanted light emission.

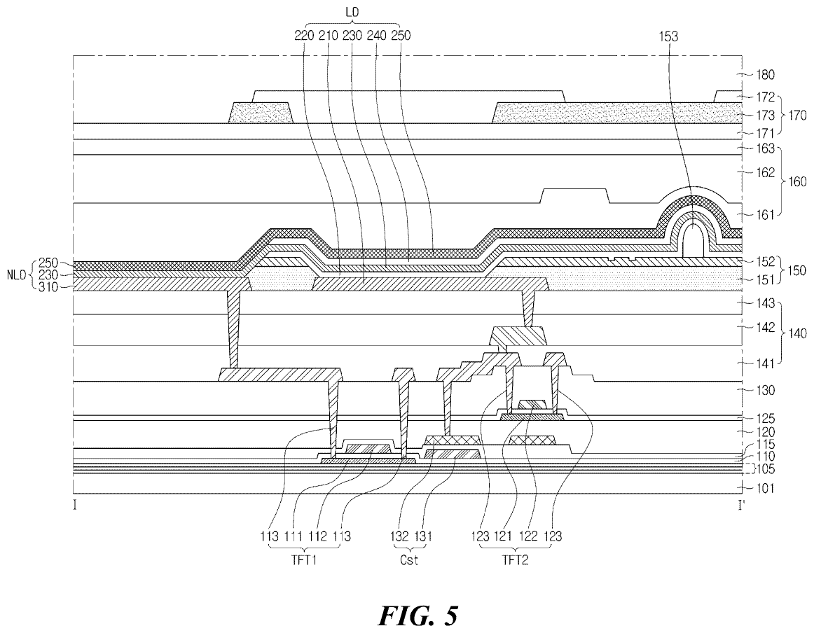

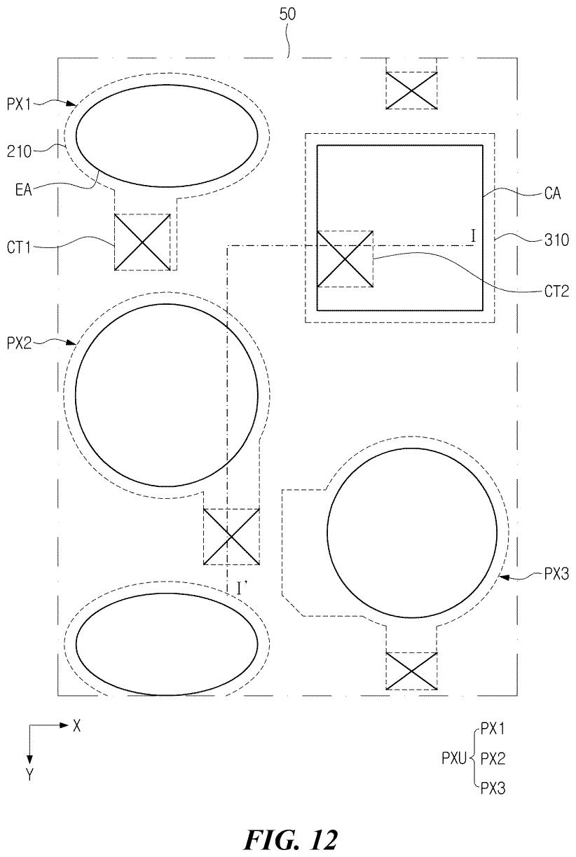

FIG. 5 is a cross-sectional view illustrating a stacked shape of the display device according to an example embodiment. In more detail, FIG. 5 illustrates a cross-sectional view according to I-I′ line in FIG. 12 which will be described below.

Referring to FIG. 5, the display panel 50 may include a substrate 101, a light emitting layer, and a circuit element layer disposed on the substrate 101. The circuit element layer may include the one or more thin film transistors TFT1 and TFT2, and the storage capacitor Cst, and the light emitting layer may include the light emitting element LD and a non-light emitting element NLD.

The substrate 101 supports various components of the display panel 50. The substrate 101 may be formed of a transparent insulating material, for example, glass, plastic, and the like. When the substrate 101 is formed of plastic, it may be referred to as a plastic film or a plastic substrate. For example, the substrate 101 may be in a film form which includes one among polyimide polymer, polyester polymer, silicon polymer, acrylic polymer, polyolefin polymer, and a copolymer thereof, but the example embodiments of the present disclosure are not limited thereto. Also, when the substrate 101 is formed of plastic, the substrate 101 may be formed in a dual structure. For example, the substrate 101 may have a structure having an adhesive layer between a first polyimide layer and a second polyimide layer. For example, the substrate 101 may have a structure which includes an inter-layer insulating layer formed of an inorganic insulating material and interposed between the first polyimide layer and the second polyimide layer. For example, the inter-layer insulating layer may include any one of a silicon oxide (SiOx) film, a silicon nitride (SiNx) film, and a silicon oxynitride (SiON) film, but not limited thereto,

When the substrate 101 is formed of glass, the substrate 101 may be referred to as a glass substrate. For example, the glass substrate may further include a shielding metal (not illustrated) below the thin film transistor TFT1 and TFT2, and may serve to protect the device from external light or signal interference.

On the substrate 101, a first buffer layer 105 may be disposed. The first buffer layer 105 may delay dispersion of moisture and/or oxygen which may permeate the substrate 101. The first buffer layer 105 may include an inorganic matter, an organic matter, or organic/inorganic composites such as oxides and nitrides, and may be formed in a single layer or multi-layer structure. For example, the first buffer layer 105 may have a structure of three or more layers consisting of silicon oxide, silicon nitride, and silicon oxynitride. For example, the first buffer layer 105 may be formed as a single layer of any one of a silicon oxide (SiOx) film, a silicon nitride (SiNx) film, and a silicon oxynitride (SiON) film, or a multilayer thereof. For example, the first buffer layer 105 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto. However, the first buffer layer 105 may be excluded in accordance with the structure or properties of the display device.

The thin film transistors TFT1 and TFT2 for driving the light emitting element LD may be disposed on the substrate 101. In FIG. 5, only part of various transistors which may be included in the display device 1 (FIG. 1) is illustrated for convenience of description. In addition, an example in which the thin film transistors TFT1 and TFT2 have a coplanar structure is described below, however, the thin film transistors TFT1 and TFT2 may be implemented in various structures such as a staggered structure and the like.

The first thin film transistor TFT1 may include a semiconductor layer 111, a gate electrode 112, and source and drain electrodes 113, which are disposed on the first buffer layer 105.

The semiconductor layer 111 may be formed of polysilicon p-Si, and in this case, a certain region may be doped with impurities. In addition, the semiconductor layer 111 may be formed of amorphous silicon a-Si, or various organic semiconductor materials such as pentacene. The semiconductor layer 111 may be formed of an oxide. The material configuring the semiconductor layer 111 is not limited to the example embodiments described above. The semiconductor layer 111 may be referred to as an active layer.

In the semiconductor layer 111, a channel may be formed when the first thin film transistor TFT1 is operated. The semiconductor layer 111 may include a channel region, a source region, and a drain region. The channel region may be disposed to overlap the gate electrode 112, and may be formed between the source region and the drain region. The source region and the drain region may be connected to the source electrode and the drain electrode 113 through a contact hole, respectively.

The gate electrode 112 may be disposed to overlap the channel region of the semiconductor layer 111 on the semiconductor layer 111. The gate electrode 112 may be formed in a single layer or multi-layer structure made of various conductive materials, for example, magnesium (Mg), aluminum (Al), nickel (Ni), chrome (Cr), molybdenum (Mo), tungsten (W), gold (Au), or an alloy thereof, but example embodiments of the present disclosure are not limited thereto.

A first insulation layer 110 may be disposed between the semiconductor layer 111 and the gate electrode 112. The first insulation layer 110 may be a layer for insulating the semiconductor layer 111 and the gate electrode 112 from each other, and may be formed of an insulating material. For example, the first insulation layer 110 may be formed in a single layer or multi-layer structure of silicon oxide SiOx, or silicon nitride SiNx, but is not limited thereto. For example, the first insulation layer 110 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The source and drain electrodes 113 may be electrically connected to the source region and the drain region of the semiconductor layer 111, respectively, and may be spaced apart from each other. The source and drain electrodes 113 may be formed in a single layer or multi-layer structure formed of a conductive material, for example, copper (Cu), aluminum (Al), molybdenum (Mo), titanium (Ti), or an alloy thereof, but is not limited thereto.

At least one insulation layer may be interposed between the source and drain electrodes 113 and the gate electrode 112. For example, between the source and drain electrodes 113 and the gate electrode 112, a second insulation layer 115, a second buffer layer 120, a third insulation layer 125, and a fourth insulation layer 130 may be interposed. Here, the second insulation layer 115 may be formed to cover the gate electrode 112. For example, the second insulation layer 115 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The second thin film transistor TFT2 may include a semiconductor layer 121, a gate electrode 122, and source and drain electrodes 123, which are disposed on the second buffer layer 120.

The semiconductor layer 121 may be formed of an oxide semiconductor, and may be formed of an oxide semiconductor or various organic semiconductors such as amorphous silicon (a-Si), polycrystalline silicon (poly-Si), or pentacene, but is not limited thereto. The semiconductor layer 121 may be referred to as an active layer.

In the semiconductor layer 121, a channel may be formed when the second thin film transistor TFT2 is operated. The semiconductor layer 121 may include a channel region, a source region, and a drain region. The channel region may be disposed to overlap the gate electrode 122, and may be formed between the source region and the drain region. The source region and the drain region may be connected to the source electrode and the drain electrode 123 through a contact hole, respectively.

The gate electrode 122 may be disposed to overlap the channel region of the semiconductor layer 121 on the semiconductor layer 121. The gate electrode 122 may be formed in a single layer or multi-layer structure made of various conductive materials, for example, magnesium (Mg), aluminum (Al), nickel (Ni), chrome (Cr), molybdenum (Mo), tungsten (W), gold (Au), or an alloy thereof, but example embodiments of the present disclosure are not limited thereto.

The third insulation layer 125 may be disposed between the semiconductor layer 121 and the gate electrode 122. The third insulation layer 125 may be a layer for insulating the semiconductor layer 121 and the gate electrode 122 from each other, and may be formed of an insulating material. For example, the third insulation layer 125 may be formed in a single layer or multi-layer structure of silicon oxide SiOx, or silicon nitride SiNx, but is not limited thereto. For example, the third insulation layer 125 may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The source and drain electrodes 123 may be electrically connected to the source region and the drain region of the semiconductor layer 121, respectively, and may be spaced apart from each other. The source and drain electrodes 123 may be formed in a single layer or multi-layer structure formed of a conductive material, for example, copper (Cu), aluminum (Al), molybdenum (Mo), titanium (Ti), or an alloy thereof, but is not limited thereto.

At least one insulation layer may be interposed between the source and drain electrodes 123 and the gate electrode 122. For example, between the source and drain electrodes 123 and the gate electrode 122, the fourth insulation layer 130 may be interposed. Here, the fourth insulation layer 130 may be formed to cover the gate electrode 122.

The insulation layers 110, 115, 125 and 130 may be formed in a single layer or multi-layer structure of silicon oxide SiOx, or silicon nitride SiNx.

In the illustrated example embodiment, the first thin film transistor TFT1 is electrically connected to a charge generation layer 230, that is, the common node NC (see FIG. 2) of the light emitting element LD which will be described below. For example, the drain electrode 113 of the first thin film transistor TFT1 may be electrically connected to the charge generation layer 230 of the light emitting element LD through the non-light emitting element NLD. In addition, the source electrode 113 of the first thin film transistor TFT1 may be electrically connected to the common node reset voltage line VcglL (see FIG. 2) extending on the substrate 101. Such a first thin film transistor TFT1 may be, for example, the eighth transistor T8, which is illustrated in FIG. 2.

In addition, in the illustrated example embodiment, the second thin film transistor TFT2 is electrically connected to the light emitting element LD which will be described below, through an auxiliary electrode 320. Such a second thin film transistor TFT2 may be, for example, one among the driving transistor DT, the fifth transistor T5, and the sixth transistor T6 which are illustrated in FIG. 2, but is not limited thereto.

The storage capacitor Cst may be further disposed on the substrate 101. The storage capacitor Cst may consist of a first electrode 131 disposed on the first insulation layer 110 and a second electrode 132 disposed on the second insulation layer 115. The first electrode 131 and/or the second electrode 132 of the storage capacitor Cst may be electrically connected to the source and/or drain electrode of at least one thin film transistor TFT1 and TFT2. In the illustrated example embodiment, the second electrode 132 of the storage capacitor Cst is connected to the first thin film transistor TFT1, but a connection relationship thereof is not limited thereto.

A planarization layer 140 may be formed on the transistors TFT1 and TFT2 and the storage capacitor Cst.

The planarization layer 140 may be provided to ease a step difference among components of the lower side. The planarization layer 140 may be formed of an organic matter such as polyimide, benzocyclobutene series resin, acrylate, and the like. The planarization layer 140 may be formed in a multi-layer structure as illustrated. In the illustrated example embodiment, the planarization layer 140 consists of two layers 141 and 142, however, in various other example embodiments, the planarization layer 140 may be formed in a multi-layer structure consisting of three or more layers. One or more conductive layers may be formed between the planarization layers 140 formed in a multi-layer structure.

For example, between the first and second planarization layers 141 and 142, a connection electrode 144 may be formed. The connection electrode 144 may be connected to the drain electrode 113 of the thin film transistor TFT1 through a connection electrode contact hole penetrating a protection layer 135 and the first planarization layer 141. The connection electrode 144 may be formed of a material having a low resistivity which is the same or similar to that of the drain electrode 113, but is not limited thereto.

In an example embodiment, a protection layer may be further formed between the transistors TFT1 and TFT2 and the planarization layer 140. The protection layer may be formed in a single layer or multi-layer structure of silicon oxide SiOx, or silicon nitride SiNx. For example, the protection layer may be formed by inorganic film in a single layer or in multiple layers, for example, the inorganic film in a single layer may be a silicon oxide (SiOx) film, a silicon nitride (SiNx) film or silicon oxynitride (SiON) film, and inorganic films in multiple layers may formed by alternately stacking at least one of one or more silicon oxide (SiOx) films, one or more silicon nitride (SiNx) films and one or more silicon oxynitride (SiON) films, and one or more amorphous silicon (a-Si), but the present disclosure is not limited thereto.

The light emitting element LD may be formed on the planarization layer 140. In an example embodiment, the light emitting element LD may have a tandem structure. In such an example embodiment, the light emitting element LD may have a structure in which the anode electrode 210, the first light emitting unit LD1, the charge generation layer 230, the second light emitting unit LD2, and a cathode electrode 250 are stacked.

The anode electrode 210 may be connected to the connection electrode 144 through a contact hole. The anode electrode 210 may be connected to the first thin film transistor TFT1 through the connection electrode 144.

The anode electrode 210 may include a metal material having a high reflectance such as a stacked structure (Ti/Al/Ti) of aluminum (Al) and titanium (Ti), a stacked structure (ITO/Al/ITO) of aluminum (Al) and ITO (Indium Tin Oxide), or an APC alloy, and may be formed of a single layer or a multi-layer, but example embodiments of the present disclosure are not limited thereto.

A bank 150 may be formed on the anode electrode 210. The bank 150 may be disposed to cover one region of the anode electrode 210, for example, an edge of the anode electrode 210, and a remaining other region, for example, a center region thereof. The bank 150 is formed to be wide on the substrate 101. An exposed region of the anode electrode 210 not covered by the bank 150 may be defined as a light emitting region.

The bank 150 may be formed of an opaque material to prevent an optical interference between adjacent pixels. The bank 150 may include a black-based material, and may include a light shielding material formed of at least one among, for example, a color pigment (a black pigment), a black dye, organic black, and carbon (black bank). Alternatively, the bank 150 may be formed of an organic material such as a benzocyclobutene resin, a polyimide resin, an acrylic resin, or photosensitive polymer, but the example embodiments of the present disclosure are not limited. When the bank 150 is formed of the black-based material, the bank 150 may shield external light, and thus, may further improve luminance of the display device 1. At this instance, the bank 150 may serve to absorb light reflected from a lower side of the bank 150 among light incident from the outside.

In an example embodiment, the bank 150 may be in a multi-layer structure. In such an example embodiment, part (for example, a lower layer 151) of the multi-layer may include a black-based material, and another part (for example, an upper layer 152) thereof may include a transparent-based material.

For example, the bank 150 may include a first bank and a second bank. The first bank may be made of an opaque material (e.g., black material) to suppress the optical interference between adjacent sub-pixels. The second bank may be made of a transparent material. The first bank and the second bank may include, but is not limited to, a light-shielding material made of at least one of a color pigment, an organic black material, and carbon.

Meanwhile, the first bank and the second bank may be formed as separate configurations, but may also be formed integrally to form one bank.

The first bank and the second bank may be disposed at a boundary between the plurality of subpixels and suppress a color mixture of light beams from the plurality of subpixels.

In an example embodiment, at least one trench recessed in a downward direction may be formed on an upper surface of the bank 150. In addition, at least one spacer 153 may be further formed on the bank 150. The trench and spacer 153 prevent direct transmission of impact from the outside, thereby protecting the light emitting element LD.

A first light emitting unit 220 may be formed on the exposed region of the anode electrode 210 which is not covered. The first light emitting unit 220 may have a structure in which a hole transporting layer and the first light emitting layer are stacked.

The charge generation layer 230 may be formed on the first light emitting unit 220. A second light emitting unit 240 may be formed on the charge generation layer 230. The second light emitting unit 240 may have a structure in which the second light emitting layer and an electron transporting layer are stacked.

The cathode electrode 250 may be formed on the second light emitting unit 240. The cathode electrode 250 may be connected to the low potential driving voltage line PL2 (FIG. 2) on an outermost side of the substrate 101. The cathode electrode 250 may include a transparent conductive material or metal such as ITO (Indium Tin Oxide) or IZO (Indium Zinc Oxide) through which the visible light is transmitted, but the example embodiments of the present disclosure are not limited thereto.

The cathode electrode 250 and the charge generation layer 230 may be formed wide on the substrate 101. For example, one or more layers configuring the cathode electrode 250 and the charge generation layer 230 may extend long to the outside of the substrate 101.

A common node reset electrode 310 may be further formed on the planarization layer 140. The common node reset electrode 310 may be formed on a same layer as the anode electrode 210. The common node reset electrode 310 may be electrically connected to the first thin film transistor TFT1 through a contact hole penetrating the planarization layer 140.

An upper surface of the common node reset electrode 310 may be in contact with the charge generation layer 230. As a result, the charge generation layer 230 may be electrically connected to the common node reset voltage line VegIL through the common node reset electrode 310 and the first thin film transistor TFT1.

The cathode electrode 250 may be further formed on the common node reset electrode 310. The common node reset electrode 310, the charge generation layer 230, and the cathode electrode 250 may form the non-light emitting element NLD.

Between the charge generation layer 230 and the cathode electrode 250 of the non-light emitting element NLD, at least part of various layers configuring the second light emitting unit 240 may be further interposed. For example, between the charge generation layer 230 and the cathode electrode 250 of the non-light emitting element NLD, the electron transporting layer configuring the second light emitting unit 240 may be further interposed.

The charge generation layer 230, the electron transporting layer and the cathode electrode 250 may extend long from the light emitting element LD to the non-light emitting element NLD. That is, the charge generation layer 230, the electron transporting layer and the cathode electrode 250 are shared between the light emitting element LD and the non-light emitting element NLD, and may be formed through one process.

In an example embodiment as above, the light emitting element LD has a structure in which the first light emitting unit 220 including the anode electrode 210 and the first light emitting layer, the second light emitting unit 240 including the charge generation layer 230 and the second light emitting layer, and the cathode electrode 250 are stacked. The non-light emitting element NLD has a structure in which the common node reset electrode 310, the charge generation layer 230, and the cathode electrode 250 are stacked.

A detailed structure of the light emitting element LD and the non-light emitting element NLD will be described with reference to the drawings hereinafter.

An encapsulation layer 160 may be formed on the light emitting element LD. The encapsulation layer 160 may block permeation of moisture or oxygen from the outside to the substrate 101 vulnerable to the moisture or oxygen from the outside. In an example embodiment, the encapsulation layer 160 may include at least one layer of an inorganic encapsulation layer and at least one layer of an organic encapsulation layer, but is not limited thereto. Hereinafter, a structure in which a first encapsulation layer 161, a second encapsulation layer 162, and a third encapsulation layer 163 are sequentially stacked will be taken as an example.

The first encapsulation layer 161 is formed on the substrate 101 on which the cathode electrode 250 is formed. The third encapsulation layer 163 may be formed on the substrate 101 on which the second encapsulation layer 162 is formed, and may be formed to surround an upper surface, a lower surface, and a side surface of the second encapsulation layer 162 together with the first encapsulation layer 161. The first encapsulation layer 161 and the third encapsulation layer 163 may minimize or prevent permeation of moisture or oxygen from the outside to the light emitting element LD.

The first encapsulation layer 161 and the third encapsulation layer 163 may be formed of an inorganic insulating material which can be deposited at a low temperature such as silicon nitride SiNx, silicon oxide SiOx, silicon oxynitride SiON, or oxide aluminum Al₂O₃, but not limited thereto. As the first encapsulation layer 161 and the third encapsulation layer 163 are deposited in a low-temperature atmosphere, the first encapsulation layer 161 and the third encapsulation layer 163 may prevent the light emitting element LD vulnerable to a high-temperature atmosphere from being damaged during the deposition process of the first encapsulation layer 161 and the third encapsulation layer 163.

The second encapsulation layer 162 serves as a buffer which eases stress between each layers due to bending of the display device 1 (see FIG. 1), and may planarize a step difference between the layers. The second encapsulation layer 162 may be formed of a non-photosensitive organic insulating material such as an acryl resin, an epoxy resin, a phenolic resin, a polyamide resin, a polyimide resin, and polyethylene or silicon oxycarbonate SiOC, or a photo-sensitive organic insulating material such as photo acryl, but is not limited thereto.

When the second encapsulation layer 162 is formed in an ink jet manner, a dam for preventing the second encapsulation layer 182 in a liquid form from dispersing to an edge of the substrate 101 may be disposed. In such an example embodiment, the dam may be disposed closer to the edge of the substrate 101 than the second encapsulation layer 162. That is, the second encapsulation layer 162 may be disposed on an inside of the dam. Through the dam, it is possible to prevent dispersion of the second encapsulation layer 162 toward a pad region in which a conductive pad disposed on an outermost side of the substrate 101 is disposed. At this instance, the first encapsulation layer 161 and the third encapsulation layer 163 may extend to an outside of the substrate 101 across the dam.

Alternatively, the encapsulation layer includes a first inorganic encapsulation layer, a first organic encapsulation layer, a second inorganic encapsulation layer, a second organic encapsulation layer, and a third inorganic encapsulation layer stacked sequentially. However, the present disclosure is not limited thereto.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

A touch layer, a color filter layer, and one or more optical functional layers may be further disposed on the encapsulation layer 160.

In an example embodiment, the touch layer may include a touch electrode or a touch sensor electrode. In such an example embodiment, the touch electrode or the touch sensor electrode may have a mesh shape. In another example embodiment, the touch layer may include a touch line or a touch routing line formed on the outside of the display panel 50.

The color filter layer may include a third buffer layer 171, a color filter 172, and a black matrix 173 formed on the encapsulation layer 160. The color filter 172 may block or allow a certain color from light emitted in the light emitting region to pass therethrough. For example, the color filter 172 may be in contact with a side surface and an upper surface of the black matrix 173.

The black matrix 173 may be disposed between the color filters 172, may distinguish each pixel PX, and may prevent an optical interference between adjacent pixels PX.

A planarization layer 180 may be further disposed on the color filter layer. The planarization layer 180 may serve to planarize a step difference formed by the color filter 172. For example, the planarization layer 180 may include an organic insulating material.

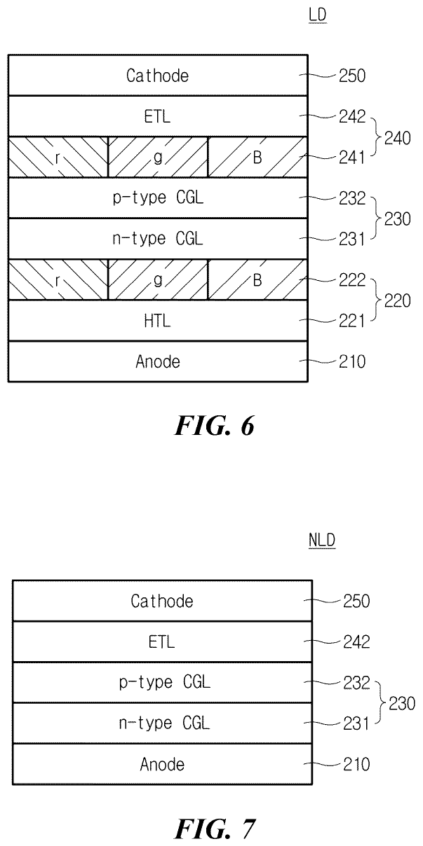

FIG. 6 is a view illustrating a structure of the light emitting element according to an example embodiment.

Referring to FIG. 6, the light emitting element LD according to an example embodiment has a tandem structure in which two light emitting units 220 and 240 are connected in series and emit light. In more detail, the light emitting element LD includes a first electrode 210 and a second electrode 250 opposed to each other, the first light emitting unit 220 and the second light emitting unit 240 disposed between the first electrode 210 and the second electrode 250, and the charge generation layer 230 disposed between the first light emitting unit 220 and the second light emitting unit 240.

Here, the first electrode 210 may be an anode electrode, and the second electrode 250 may be a cathode electrode. In addition, the first light emitting unit 220 may be disposed adjacent to the first electrode 210 and the second light emitting unit 240 may be disposed adjacent to the second electrode 250.

The first light emitting unit 220 may include the hole transporting layer HTL 221, and a first light emitting layer 222 disposed on the hole transporting layer 221. The first electrode 210, the hole transporting layer 221, and the first light emitting layer 222 may be stacked sequentially. According to an example embodiment, a hole injection layer HIL may be further disposed together with the hole transporting layer 221, or between the first electrode 210 and the hole transporting layer 221. In addition, a hole block layer HBL may be further disposed on the first light emitting layer 222.

The second light emitting unit 240 includes a second light emitting layer 241 and an electron transporting layer ETL 242 disposed on the second light emitting layer 241. The second light emitting layer 241, the electron transporting layer ETL 242 and the second electrode 250 may be stacked sequentially. According to some example embodiment, the hole transporting layer may be further disposed below the second light emitting layer 241. In addition, according to some example embodiment, the hole block layer may be further disposed together with the electron transporting layer 242, or between the electron transporting layer 242 and the second electrode 250, but not limited thereto.

The first and second light emitting layers 222 and 241 may include a plurality of light emitting materials which emit light in different colors. For example, each of the first and second light emitting layers 222 and 241 may include a blue light emitting material B, a red light emitting material R, and a green light emitting material G. Each of the light emitting materials R, G, and B may be formed per region in the light emitting layers 222 and 241.

The charge generation layer 230 is disposed between the light emitting units 220 and 240, adjusts charges between the light emitting units 220 and 240, and makes balance of the charges. The charge generation layer 230 may include a negative charge generation layer (an n-type charge generation layer 231) disposed adjacent to the first light emitting unit 220 and configured to supply a charge to the first light emitting unit 220 and a positive charge generation layer (a p-type charge generation layer 232) disposed adjacent to the second light emitting unit 240 and configured to supply a hole to the second light emitting unit 240.

The charge generation layer 230 may divide an emission burden of the first light emitting unit 220 and a second light emitting unit 240 by dividing a voltage. For example, the charge generation layer 230 may allow an electron to enter the electron transporting layer 242 and a hole to enter the hole transporting layer 221 easily. As such, through the negative charge generation layer 231 and the positive charge generation layer 232, light emission efficiency of the light emitting element LD may further increase.

The charge generation layer 230 may be formed of metal such as aluminum (Al), or a transparent conductive material such as indium tin oxide (ITO) and the like. Alternatively, the charge generation layer 230 may be formed by doping an n-type material and a p-type material on an organic matter.

When a voltage is applied to the first electrode 210 and the second electrode 250 of the light emitting element LD as above, an electron is generated from the negative charge generation layer 231 and moves to the first light emitting unit 220, and a hole is injected into the first light emitting unit 220 from the first electrode 210, and is combined with the electron of the first light emitting unit 220. Through this, the first light emitting unit 220 may emit light.

Similarly, an electron is injected into the second light emitting unit 240 from the second electrode 250, and a hole is generated in the positive charge generation layer 232, the hole moves to the second light emitting unit 240 and is combined with the electron in the second light emitting unit 240. Through this, the second light emitting unit 240 may emit light.

The light emitting element LD in such a tandem structure may increase release of a photon of the electron and the hole through the charge generation layer 230. The light emitting element LD in the tandem structure may increase a use lifespan and current efficiency of the organic light emitting element, and may supplement an insufficient part in factors determining an image quality such as the luminance because two light emitting layers generate light.

FIG. 7 is a view illustrating a structure of the non-light emitting element according to an example embodiment.

Referring to FIG. 7, the non-light emitting element NLD according to an example embodiment includes a first electrode 310 and the second electrode 250 opposed to each other, and the charge generation layer 230 disposed between the first electrode 310 and the second electrode 250. Here, the first electrode 310 may be the common node reset electrode and the second electrode 250 may be the cathode electrode.

The charge generation layer 230 is disposed to be in direct contact with the first electrode 310. In an example embodiment, the charge generation layer 230 may include the negative charge generation layer 231 disposed adjacent to the first electrode 310, and the positive charge generation layer 232 disposed adjacent to the second electrode 250.

The charge generation layer 230 may be formed of metal such as aluminum (Al) and the like, or a transparent conductive material such as indium tin oxide (ITO) and the like. Alternatively, the charge generation layer 230 may be formed by doping an n-type material and a p-type material on an organic matter.

At least one organic layer may be further included between the charge generation layer 230 and the second electrode 250. For example, the electron transporting layer 242 and/or the hole block layer may be further disposed between the charge generation layer 230 and the second electrode 250.

In comparison with the light emitting element LD illustrated in FIG. 6, the non-light emitting element NLD does not include the light emitting layers 222 and 241, and is disposed such that the charge generation layer 230 is in direct contact with the first electrode 310. The non-light emitting element NLD does not include the light emitting layers 222 and 241, and therefore, unwanted light emission in the non-light emitting element NLD can be prevented.

At least one organic layer and the second electrode 250 formed on the charge generation layer 230 of the non-light emitting element NLD are the same as part of the second light emitting unit 240 and the second electrode 250 formed on the charge generation layer 230 of the light emitting element LD. For example, the electron transporting layer 242 and the second electrode 250 are formed of the same material through one process in the non-light emitting element NLD and the light emitting element LD. Therefore, the electron transporting layer 242 and the second electrode 250 extend from the light emitting element LD to the non-light emitting element NLD, and are shared between the light emitting element LD and the non-light emitting element NLD.

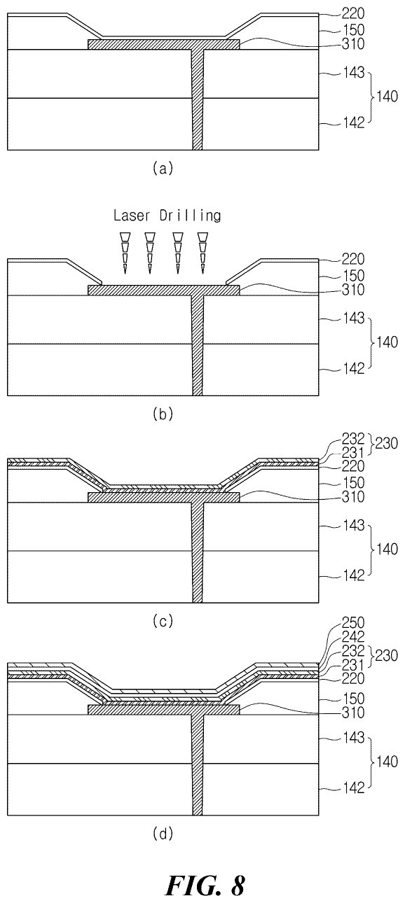

FIG. 8 is a view illustrating a method for forming the non-light emitting element according to an example embodiment. In more detail, FIG. 8 illustrates a method for forming the non-light emitting element illustrated in FIG. 7.

Referring to FIGS. 5 to (a) of FIG. 8 together, the planarization layer 140 including a second planarization layer 142 and a third planarization layer 143 is formed on the substrate 101. The common node reset electrode 310 and the anode electrode 210 may be formed on the planarization layer 140.

The bank 150 may be formed on the common node reset electrode 310. The bank 150 may be formed such that the bank 150 does not cover at least one region of the common node reset electrode 310, for example, a center region.

The first light emitting unit 220 may be formed on the bank 150, and the anode electrode 210 and the common node reset electrode 310 not covered by the bank 150 and exposed to an upper side. For example, the hole transporting layer 221 and the first light emitting layer 222 may be stacked sequentially. An organic layer configuring the first light emitting unit 220 may be formed wide on the substrate 101 and may be stacked on the common node reset electrode 310 as well.

Referring to (b) of FIG. 8, a laser drilling or laser etching process may be formed with respect to the organic layer formed on the common node reset electrode 310. Through the laser drilling or laser etching process, the first light emitting unit 220 stacked on the common node reset electrode 310 may be etched to make a hole. The common node reset electrode 310 is not etched by the laser, and may be exposed to an upper side through the hole.

Referring to (c) of FIG. 8, the charge generation layer 230 is formed on the first light emitting unit 220. In more detail, the negative charge generation layer 231 and the positive charge generation layer 232 may be sequentially stacked. In the non-light emitting element NLD, the charge generation layer 230 may be in direct contact with the common node reset electrode 310 exposed to the upper side through the hole.

Referring to (d) of FIG. 8, the second light emitting unit 240 and the cathode electrode 250 may be further formed on the charge generation layer 230. For example, the second light emitting layer 241 and the electron transporting layer 242 may be sequentially stacked. The second light emitting layer 241 is patterned in the light emitting element LD, and is not formed on the common node reset electrode 310. The electron transporting layer 242 and the cathode electrode 250 may be formed wide on the substrate 101, and may be sequentially stacked on the charge generation layer 230 of the non-light emitting element NLD.

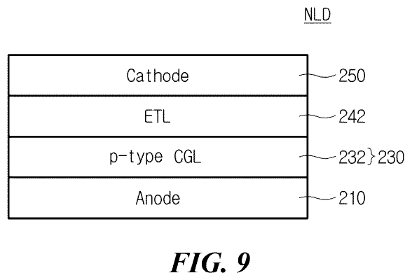

FIG. 9 is a view illustrating a configuration of a non-light emitting element according to another example embodiment.

Referring to FIG. 9, the non-light emitting element NLD according to another example embodiment includes the first electrode 310 and the second electrode 250 opposed to each other, and the charge generation layer 230 disposed between the first electrode 310 and the second electrode 250. Here, the first electrode 310 may be the common node reset electrode and the second electrode 250 may be the cathode electrode.

The charge generation layer 230 is disposed to be in direct contact with the first electrode 310. In comparison with the example embodiment in FIG. 7, the charge generation layer 230 may include only the positive charge generation layer 232.

When the common node reset voltage Vcgl (see FIG. 2) applied to the common node reset electrode 310 has a positive value, and the common node reset electrode 310 is in direct contact with the positive charge generation layer doped with the p-type material, a forward current path is formed and therefore, the common node reset voltage Vogl may be transmitted to the charge generation layer 230 more effectively.

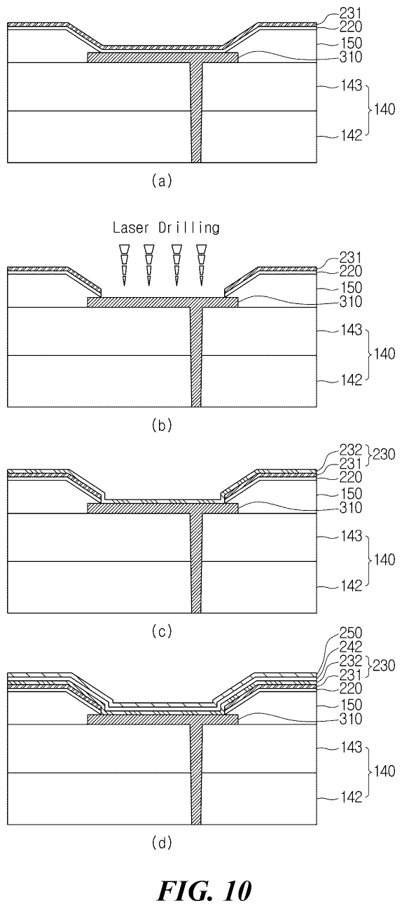

FIG. 10 is a view illustrating a method for forming the non-light emitting element according to another example embodiment. In more detail, FIG. 10 illustrates a method for forming the non-light emitting element illustrated in FIG. 9.

Referring to FIGS. 5, 6, 9 and (a) of FIG. 10 together, the planarization layer 140 including the second planarization layer 142 and the third planarization layer 143 is formed on the substrate 101. The common node reset electrode 310 and the anode electrode 210 together may be formed on the planarization layer 140.

The bank 150 may be formed on the common node reset electrode 310. The bank 150 may be formed such that the bank 150 does not cover at least one region of the common node reset electrode 310, for example, a center region.

The first light emitting unit 220 may be formed on the bank 150, and the anode electrode 210 and the common node reset electrode 310 not covered by the bank 150 and exposed to an upper side. For example, the hole transporting layer 221 and the first light emitting layer 222 may be stacked sequentially. An organic layer configuring the first light emitting unit 220 may be formed wide on the substrate 101 and may be stacked on the common node reset electrode 310.

In addition, part of the charge generation layer 230 may be further formed on the first light emitting unit 220. In more detail, the negative charge generation layer 231 may be formed on the first light emitting unit 220.

Referring to (b) of FIG. 10, a laser drilling or laser etching process may be formed with respect to the organic layer formed on the common node reset electrode 310. Through the laser drilling or laser etching process, the organic layer stacked on the common node reset electrode 310, for example, the first light emitting unit 220 and the negative charge generation layer 231 may be etched to make a hole. The common node reset electrode 310 is not etched by the laser, and may be exposed to an upper side through the hole.

Referring to (c) of FIG. 10, the positive charge generation layer 232 is formed on the negative charge generation layer 231. In the non-light emitting element NLD, the positive charge generation layer 232 may be in direct contact with the common node reset electrode 310 exposed to the upper side through the hole.

Referring to (d) of FIG. 10, the second light emitting unit 240 and the cathode electrode 250 may be further formed on the positive charge generation layer 232. For example, the second light emitting layer 241 and the electron transporting layer 242 may be sequentially stacked. The second light emitting layer 241 is patterned in the light emitting element LD, and is not formed on the common node reset electrode 310. The electron transporting layer 242 and the cathode electrode 250 may be formed wide on the substrate 101, and may be sequentially stacked on the charge generation layer 230 of the non-light emitting element NLD.

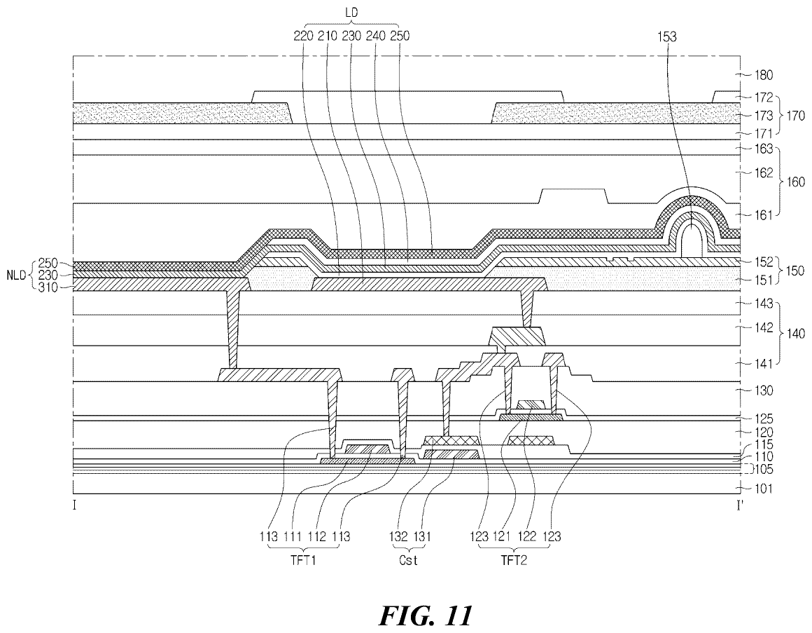

FIG. 11 is a cross-sectional view illustrating a stacked shape of a display device according to another example embodiment. In more detail, FIG. 5 illustrates a cross-sectional view taken along I-I′ line in FIG. 12 which will be described below.

In comparison with the example embodiment of FIG. 5, the black matrix 173 is further formed on the non-light emitting element NLD in the example embodiment of FIG. 11.

The black matrix 173 may include a black-based material. For example, the black matrix 173 may include a light shielding material or a light absorbing material. For example, the black matrix 173 may be formed of a material including a black pigment or a black dye.

The black matrix 173 may be further formed on the non-light emitting element NLD. For example, at least one region of the black matrix 173 may overlap the non-light emitting element NLD. In such an example embodiment, the black matrix 173 may prevent unwanted light emission which may occur in the non-light emitting element NLD from becoming visible from the outside.

FIG. 12 is a plan view illustrating a region of the display panel according to an example embodiment.

Referring to FIG. 12, an array of the pixels PX1, PX2, and PX3 are disposed on the display panel 50. Each of the pixels PX1, PX2, and PX3 may be referred to as a sub-pixel.

The pixels PX may include a red pixel PX1 configured to emit light in a red color, a green pixel PX2 configured to emit light in a green color, and a blue pixel PX3 configured to emit light in a blue color, for example. One red pixel PX1, one green pixel PX2, and one blue pixel PX3 may configure one unit pixel PXU.

However, a color and a quantity of the pixels PX1, PX2, and PX3 configuring a unit pixel PXU are not limited thereto. In various other example embodiments, a unit pixel PXU may be configured with pixels displaying cyan, magenta and yellow colors, or pixels displaying red, green, blue and white colors.

In addition, in other various example embodiments, the unit pixel PXU may include two or more red, green, and blue pixels. For example, two or more green pixels PX2 of which luminance is seen relatively low may be included in one unit pixel PXU, but is not limited thereto.

In the illustrated example embodiment, the first pixel PX1 and the second pixel PX2 are disposed parallel to each other along a second direction Y in general, and the second pixel PX2 and the third pixel PX3 are spaced apart from each other in the second direction Y. The first pixel PX1 to the third pixel PX1, PX2 and PX3 are disposed sequentially along the second direction Y. The first pixel PX1 and the third pixel PX3 may be disposed sequentially along the first direction X, and the second pixel PX2 and the third pixel PX3 may be disposed sequentially along the first direction X.

However, the arrangement of the pixels PX1, PX2 and PX3 are not limited to what is illustrated, and may be changed variously.

Each of the pixels PX1, PX2 and PX3 includes the light emitting element LD (see FIG. 5). Accordingly, each of the pixels PX1, PX2 and PX3 includes the anode electrode 210 which configures the light emitting element LD. The anode electrode 210 of the pixels PX1, PX2 and PX3 may have the same or different shape and size.

The anode electrode 210 may have not only a circular shape or an oval shape, but also a polygonal shape such as a quadrangle, a pentagon, an octagon, a diamond, and may have a shape of which at least part thereof is bent. The shape of the anode electrode 210 is not particularly limited.

In various example embodiments, the anode electrode 210 of each pixel PX1, PX2 and PX3 may have the same or different area (size). In the illustrated example embodiment, the anode electrode 210 of the second pixel PX2 of which luminance is seen relatively low may be illustrated greater than the anode electrodes 210 of other pixels PX1 and PX3, and the anode electrode 210 of the first pixel PX1 of which luminance is seen relatively high may be illustrated smaller than the anode electrodes 210 of other pixels PX2 and PX3, but the example embodiments are not limited thereto.

Such an anode electrodes 210 may be directly/indirectly connected to the driving transistor DT (see FIG. 2) through a contact hole CT1 covered by the bank 150.

Each of the pixels PX1, PX2 and PX3 has the light emitting region EA which is defined by each of the light emitting elements LD. The light emitting region EA may be defined as a region in which the anode electrode 210 is not covered by an upper insulation layer (for example, the bank 150, FIG. 5) and is exposed to an upper side. The upper insulation layer may cover an edge region of the anode electrode 210 in general, and as a result, the light emitting region EA may correspond to a center region of the anode electrode 210 in general.

A size and a shape of the light emitting region EA of each of the pixels PX1, PX2 and PX3 may be the same or different. A size and a shape of the light emitting region EA may follow a size and a shape of the anode electrode 210, but are not limited thereto.

In addition, a quantity of the light emitting region EA provided in one pixel PX1, PX2 and PX3 may be one or more, and may be the same or different with respect to the pixels PX1, PX2 and PX3. In an example embodiment, one light emitting region EA is formed in part of the pixels PX1, PX2 and PX3, and a plurality of light emitting regions EA may be formed in the remaining other of the pixels PX1, PX2 and PX3. However, the quantity of the light emitting region EA is not limited thereto.

In an example embodiment, in the unit pixel PXU, the common node reset electrode 310 may be provided adjacent to the pixels PX1, PX2 and PX3. For example, the common node reset electrode 310 may be formed in each of the unit pixel PXU as illustrated.

In an example embodiment, the common node reset electrode 310 may be formed per pixel or per plurality of pixels PX1, PX2 and PX3. For example, as illustrated, the common node reset electrode 310 may be formed one per three pixels PX1, PX2 and PX3. In such an example embodiment, a ratio between the pixels PX1, PX2 and PX3 and the common node reset electrode 310 is 3:1. However, the ratio between the pixels PX1, PX2 and PX3 and the common node reset electrode 310 is not limited thereto.

The common node reset electrode 310 may be formed on the same layer as the anode electrode 210, and one region thereof may be covered by the upper insulation layer (for example, the bank 150) like the anode electrode 210. For example, an edge region of the common node reset electrode 310 may be covered by the bank 150, and a center region thereof may not be covered by the bank 150 and may be exposed to an upper side.

The exposed center region may be in direct contact with the charge generation layer 230 (see FIG. 5) as described above. As such, one region exposed without being covered by the upper insulation layer may configure a contact region CA.

Such a common node reset electrode 310 may be directly/indirectly connected to the common node reset transistor T8 (see FIG. 2) through a contact hole CT2 covered by the bank 150.

In the illustrated example embodiment, the common node reset electrode 310 may be formed parallel to the third pixel PX3 along the second direction Y. At this instance, the common node reset electrode 310 may be disposed adjacent to the first pixel PX1 and the second pixel PX2 in the first direction X. However, the arrangement relationship between the common node reset electrode 310 and the pixels PX1, PX2 and PX3 is not limited to what is illustrated, and may be changed variously.

The charge generation layer 230 is formed wide on the substrate 101 and may cover the anode electrode 210 of the plurality of pixels PX1, PX2 and PX3. At this instance, as the common node reset electrode 310 is formed one per unit pixel PXU, the common node reset voltage Vcgl (see FIG. 2) may be uniformly transmitted to the charge generation layer 230 across the entire display panel 50 (see FIG. 1).

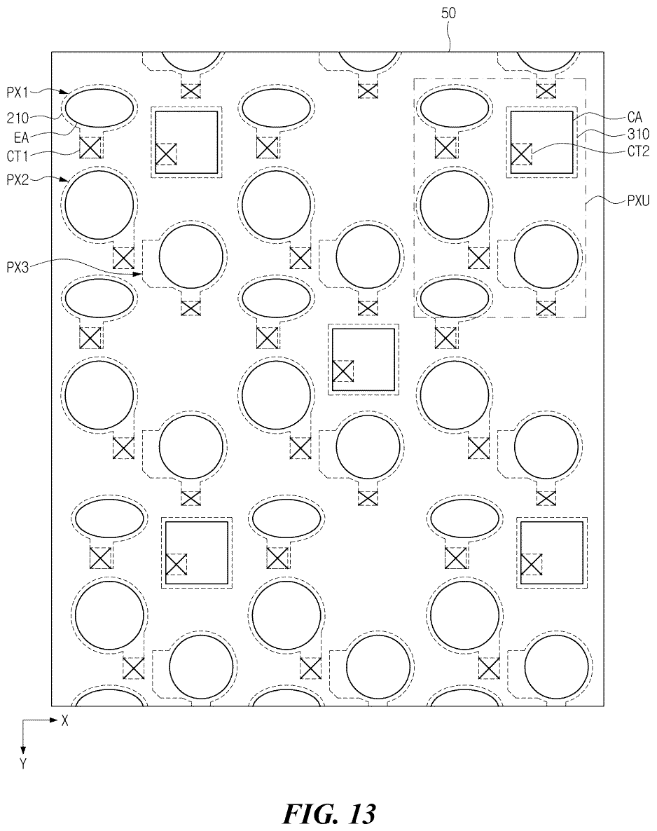

FIG. 13 is a view illustrating a region of a display panel according to another example embodiment.

In comparison with the example embodiment in FIG. 12, in the example embodiment in FIG. 13, the common node reset electrode 310 may be formed one per two or more unit pixels PXU as illustrated. For example, the common node reset electrode 310 may be formed one per six pixels PX1, PX2 and PX3. In such an example embodiment, a ratio between the pixels PX1, PX2 and PX3 and the common node reset electrode 310 is 6:1.

In an example embodiment, the display panel 50 (see FIG. 1) may be formed in a top-emission manner, the anode electrode 210 of the light emitting element LD may be formed of a material which is opaque, translucent, or has a high reflectance, and the cathode electrode 250 may be formed of a transparent material. In such an example embodiment, by adjusting the ratio between the pixels PX1, PX2 and PX3 and the common node reset electrode 310 formed of an opaque material properly, it is possible to improve an opening ratio of the pixels PX1, PX2 and PX3 and maximize the area of the light emitting region EA.

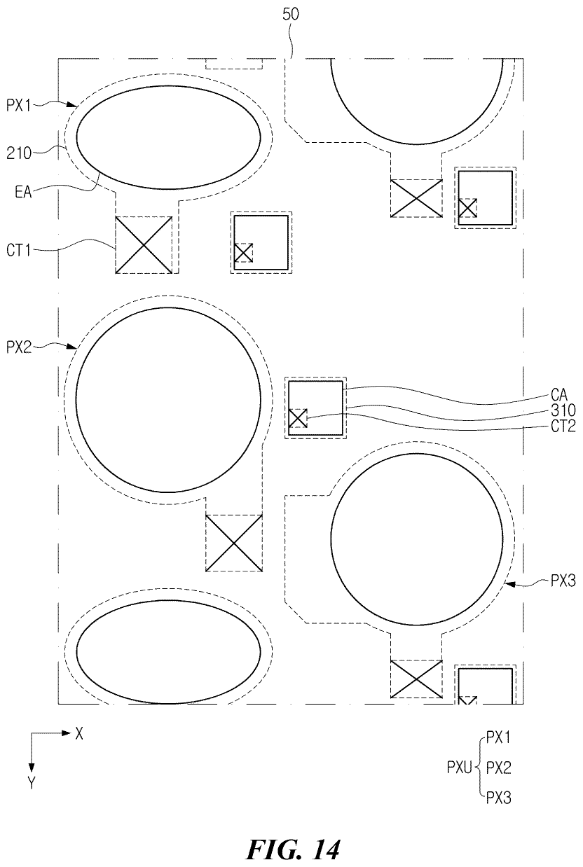

FIG. 14 is a view illustrating a region of a display panel according to still another example embodiment.

In comparison with the example embodiment in FIG. 12, in the example embodiment in FIG. 14, the common node reset electrode 310 may be formed one per pixel PX1, PX2 and PX3. In such an example embodiment, a ratio between the pixels PX1, PX2 and PX3 and the common node reset electrode 310 is 1:1. The common node reset electrode 310 may be disposed adjacent to one side of the pixel PX1, PX2 and PX3 corresponding thereto.

As described above, when the common node reset electrode 310 is disposed per pixel PX1, PX2 and PX3, IR drop in a transmission path of the common node reset voltage Vogl is improved, thereby transmission of the common node reset voltage Vogl to the charge generation layer 230 can be made easier.

Accordingly, the display device according to example embodiments may prevent variation of a voltage of the charge generation layer by resetting a voltage of the charge generation layer during the anode reset period.

The example embodiments of the present disclosure have been described with reference to accompanying drawings. Those of ordinary skill in the art will recognize that the present disclosure may be embodied in other specific forms without departing from its spirit or essential characteristics. The described example embodiments are to be considered in all respects only as illustrative and not restrictive. The scope of the present disclosure includes those of the appended claims. All changes which come within meaning and range of equivalency of the claims are to be embraced within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including pixels,
wherein each of the pixels comprises:
a light emitting element including a plurality of light emitting units connected in series through a common node;
a driving transistor including a first electrode connected to a high potential driving voltage through a first node, a gate electrode connected to a second node, and the second electrode connected to an anode electrode of the light emitting element through a third node;
a compensation transistor connected between the second node and the third node and configured to receive a first scan signal through a gate electrode;
a switching transistor connected between a data line and the first node and configured to receive a second scan signal through a gate electrode; and
a common node reset transistor connected between the common node and a common node reset voltage and configured to receive a third scan signal through a gate electrode.

2. The display device of claim 1, further comprising:
an anode reset transistor connected between the light emitting element and an anode reset voltage and configured to receive the third scan signal through a gate electrode,
wherein the anode reset voltage and the common node reset voltage have different voltage values.

3. The display device of claim 2,
wherein when the third scan signal is applied in a turn-on level during an anode reset period within one frame, the anode reset transistor is turned on and applies an anode reset voltage to the anode electrode, and the common node reset transistor is turned on and applies the common node reset voltage to the common node.

4. The display device of claim 2, further comprising:
an initialization transistor connected between an initialization voltage line and the second node and configured to receive a fourth scan signal through a gate electrode;
a first light emitting transistor connected between the high potential driving voltage and the first node and configured to receive a light emitting signal through a gate electrode;
a second light emitting transistor connected between the third node and the light emitting element and configured to receive the light emitting signal through a gate electrode;
an on-bias transistor connected between the first node and an on-bias voltage and configured to receive the third scan signal through a gate electrode; and
a storage capacitor connected between the high potential driving voltage and the second node.

5. The display device of claim 1,
wherein at least one of the driving transistor, the compensation transistor, the switching transistor, or the common node reset transistor is an LTPS transistor and at least one of the driving transistor, the compensation transistor, the switching transistor, or the common node reset transistor is an oxide transistor.

6. The display device of claim 1, further comprising:
a substrate;
a circuit element layer disposed on the substrate and including at least one thin film transistor; and
a light emitting element layer disposed on the circuit element layer,
wherein the light emitting element layer comprises:
the light emitting element; and
a non-light emitting element electrically connected to the common node reset transistor.

7. The display device of claim 6,
wherein the light emitting element comprises:
a first electrode;
a second electrode disposed opposed to the first electrode;
a first light emitting unit and a second light emitting unit disposed between the first electrode and the second electrode; and
a charge generation layer interposed between the first light emitting unit and the second light emitting unit and configuring the common node,
wherein the non-light emitting element comprises:
a common node reset electrode formed on a same layer as the first electrode and electrically connected to the common node reset transistor;
the charge generation layer formed on the common node reset electrode; and
a second electrode formed on the charge generation layer.

8. The display device of claim 7,
wherein the charge generation layer and the second electrode extend from the light emitting element to the non-light emitting element.

9. The display device of claim 7,
wherein the first light emitting unit comprises:
a hole transporting layer; and
a first light emitting layer disposed on the hole transporting layer,
wherein the second light emitting unit comprises:
a second light emitting layer; and
a second electron transporting layer on the second light emitting layer, and
wherein the second electron transporting layer extends from the light emitting element to the non-light emitting element.

10. The display device of claim 7,
wherein in the light emitting element and the non-light emitting element, the charge generation layer comprises:
a negative charge generation layer disposed adjacent to the first light emitting unit; and
a positive charge generation layer disposed adjacent to the second light emitting unit.

11. The display device of claim 7,
wherein in the light emitting element, the charge generation layer comprises:
a negative charge generation layer disposed adjacent to the first light emitting unit; and
a positive charge generation layer disposed adjacent to the second light emitting unit, and
wherein in the non-light emitting element, the charge generation layer comprises:
the positive charge generation layer.

12. The display device of claim 7,
wherein the common node reset electrode is formed per one, or two or more pixels.

13. The display device of claim 6,
wherein the circuit element layer comprises:
a first buffer layer disposed on the substrate;
a first semiconductor layer of a first thin film transistor disposed on the buffer layer;
a first insulation layer disposed on the first semiconductor layer;
a first gate electrode of the first thin film transistor disposed on the first insulation layer;
a second insulation layer of the first thin film transistor disposed on the gate electrode;
a second buffer layer disposed on the second insulation layer;
a second semiconductor layer of a second thin film transistor disposed on the second buffer layer;
a third insulation layer disposed on the second semiconductor layer;
a second gate electrode of the second thin film transistor disposed on the third insulation layer;
a fourth insulation layer of the second thin film transistor disposed on the gate electrode;
source and drain electrodes of each of the first and second thin film transistors disposed on the fourth insulation layer; and
a planarization layer disposed on the source and drain electrodes,
wherein the first thin film transistor is part of the driving transistor, the compensation transistor, the switching transistor, and the common node reset transistor, and
wherein the second thin film transistor is a remaining one or more of the driving transistor, the compensation transistor, the switching transistor, and the common node reset transistor.

14. The display device of claim 6, further comprising:
a color filter layer disposed on the light emitting element layer and including color filters and a black matrix disposed between the color filters,
wherein the black matrix is formed such that at least one region thereof overlaps the non-light emitting element.

15. A display device, comprising:
a substrate;
a circuit element layer disposed on the substrate and comprising at least one thin film transistor; and
a light emitting element layer disposed on the circuit element layer and comprising a light emitting element and a non-light emitting element,
wherein the light emitting element comprises:
a first electrode;
a second electrode disposed opposed to the first electrode;
a first light emitting unit and a second light emitting unit disposed between the first electrode and the second electrode; and
a charge generation layer interposed between the first light emitting unit and the second light emitting unit,
wherein the non-light emitting element comprises:
a common node reset electrode formed on a same layer as the first electrode;
the charge generation layer formed on the common node reset electrode; and
a second electrode formed on the charge generation layer.

16. The display device of claim 15,
wherein the charge generation layer and the second electrode extend from the light emitting element to the non-light emitting element.

17. The display device of claim 15,
wherein in the light emitting element and the non-light emitting element, the charge generation layer comprises:
a negative charge generation layer disposed adjacent to the first light emitting unit; and
a positive charge generation layer disposed adjacent to the second light emitting unit.

18. The display device of claim 15,
wherein in the light emitting element, the charge generation layer comprises:
a negative charge generation layer disposed adjacent to the first light emitting unit; and
a positive charge generation layer disposed adjacent to the second light emitting unit, and
wherein in the non-light emitting element, the charge generation layer comprises:
the positive charge generation layer.

19. The display device of claim 15,
wherein the circuit element layer comprises:
a driving transistor connected to the light emitting element; and
a common node reset voltage transistor including a first electrode connected to the charge generation layer through the common node reset electrode of the non-light emitting element, and a second electrode connected to a common node reset voltage.

20. The display device of claim 19, wherein the circuit element layer further comprises:
an anode reset transistor including a first electrode connected to an anode reset voltage and a second electrode connected to the light emitting element,
wherein the anode reset voltage and the common node reset voltage have each different voltage value.
